(19) United States
(12) Patent Application Publication
(10) Pub. No.: US 2020/0172675 A1
(43) Pub. Date: Jun. 4, 2020

(54) LOW-COLOR POLYMERS FOR FLEXIBLE SUBSTRATES IN ELECTRONIC DEVICES

(71) Applicant: E. I. DU PONT DE NEMOURS AND COMPANY, Wilmington, DE (US)

(72) Inventors: Nora Sabina Radu, Landenberg, PA (US); John Donald Summers, Chapel Hill, NC (US); Brian C. Auman, Avondale, PA (US); Wayne Atkinson, New Castle, DE (US); Wei Li, Middletown, DE (US); Chai Kit Ngai, Wilmington, DE (US)

(21) Appl. No.: 16/637,897

(22) PCT Filed: Aug. 8, 2018
(86) PCT No.: PCT/US2018/045722

§ 371 Date: Feb. 10, 2020

Related U.S. Application Data
(60) Provisional application No. 62/544,036, filed on Aug. 11, 2017.

(51) Int. Cl. C08G 73/10; C08J 5/18; H01L 27/32; H01L 51/00; H01L 51/52

(52) U.S. Cl. CPC C08G 73/1042; C08J 5/18; H01L 27/322; H01L 27/323; H01L 2251/5338; H01L 51/0097; H01L 51/524; C08J 2379/08; H01L 27/3244

(57) ABSTRACT

Disclosed is a solution containing a polyamic acid in a high-boiling, aprotic solvent; wherein the polyamic acid contains two or more tetracarboxylic acid components and one or more diamine components; and wherein at least one of the tetracarboxylic acid components is a quadrivalent organic group derived from an aliphatic dianhydride. Polyimide films made from the solutions are also disclosed, as are their methods of production and uses in electronic devices.

### CLAIM OF BENEFIT OF PRIOR APPLICATION

This application claims the benefit of U.S. Provisional Application No. 62/544,036, filed Aug. 11, 2017, which is incorporated in its entirety herein by reference.

### BACKGROUND INFORMATION

### Field of the Disclosure

The present disclosure relates to novel polymeric compounds. The disclosure further relates to methods for preparing such polymeric compounds and electronic devices having at least one layer comprising these materials.

### Description of the Related Art

Materials for use in electronics applications often have strict requirements in terms of their structural, optical, thermal, electronic, and other properties. As the number of commercial electronics applications continues to increase, the breadth and specificity of requisite properties demand the innovation of materials with new and/or improved properties. Polyimides represent a class of polymeric compounds that has been widely used in a variety of electronics applications.

Polyimide films can be used as a replacement for glass in electronic display devices provided that they have suitable properties. These materials can function as a component of Liquid Crystal Displays (“LCD”) where their modest consumption of electrical power, light weight, and layer flatness are critical properties for effective utility. Other uses in electronic display devices that place such parameters at a premium include device substrates, color filters, cover films, touch panels, and others.

A number of these components are important in the construction and operation of organic electronic devices having an organic light emitting diode (“OLED”). OLEDs are promising for many display applications because of their high power conversion efficiency and applicability to a wide range of end-uses. They are increasingly being used in cell phones, tablet devices, handheld/laptop computers, and other commercial products. These applications call for displays with high information content, full color, and fast video rate response time in addition to low power consumption.

In OLED displays, one or more organic electroactive layers are sandwiched between two electrical contact layers. These layers are generally formed on a substrate material, which may be rigid or flexible. In an OLED device, at least one organic electroactive layer emits light through the light-transmitting electrical contact layer upon application of a voltage across the electrical contact layers.

These devices frequently include one or more charge transport layers, which are positioned between a photoactive (e.g., light-emitting) layer and a contact layer (hole-injecting contact layer). A device can contain two or more contact layers. A hole transport layer can be positioned between the photoactive layer and the hole-injecting contact layer. The hole-injecting contact layer may also be called the anode. An electron transport layer can be positioned between the photoactive layer and the electron-injecting contact layer. The electron-injecting contact layer may also be called the cathode.

As electronics applications like OLEDs continue to be developed, the importance of materials having low-color characteristics is increasing. Many common polyimides, however, exhibit an amber color that precludes their use in some of the device applications disclosed herein. In addition to the OLEDs application, such electronic components as color filters and touch screen panels place a premium on optical transparency.

A number of materials-development strategies have been invoked towards the reduction of the color characteristics of polyimide films for use in electronic devices. Although synthetic strategies that disrupt polymer chain conformation with monomers containing flexible bridging units and/or meta linkages may seem to offer promise; the polyimides that result from such syntheses often exhibit an increased coefficient of thermal expansion (CTE), lower glass transition temperature (T_{g}), and/or lower modulus than is desirable in many end-use applications. The same property drawbacks often follow from synthetic strategies that are intended to disrupt polymer chain conformation via the introduction of monomers with bulky side groups.

A number of other strategies have been similarly unsuccessful in the preparation of polyimide films that exhibit low color. The use of aliphatic or partially-aliphatic monomers, while effective in disrupting the long-range conjugation that can lead to excessive color, has sometimes been found to lead to polyimides with reduced mechanical and thermal performance for many electronics end-uses. The use of dianhydrides with low electron affinity and/or diamines that are weak electron donors has also been attempted. Such structural modifications, however, can yield unacceptably-slow polymerization rates for use in industrial applications.

Finally; the use of very high purity monomers, particularly the diamine component of polyimides, has been attempted as a mechanism to reduce the color characteristics of these films. Industrial processing associated with this approach to low-color materials, however, is generally cost-prohibitive in commercial electronics applications.

There is thus a continuing need for low-color materials that are suitable for use in electronic devices.

### SUMMARY

There is provided a solution containing a polyamic acid in a high-boiling, aprotic solvent; wherein the polyamic acid comprises two or more tetracarboxylic acid components and one or more diamine components; and wherein at least one of the tetracarboxylic acid components is a quadrivalent organic group derived from an aliphatic dianhydride.

There is further provided a polyimide film generated from a solution containing a polyamic acid in a high-boiling, aprotic solvent; wherein the polyamic acid comprises two or more tetracarboxylic acid components and one or more diamine components; and wherein at least one of the tetracarboxylic acid components is a quadrivalent organic group derived from an aliphatic dianhydride.

There is further provided a polyimide film comprising the repeat unit of Formula I

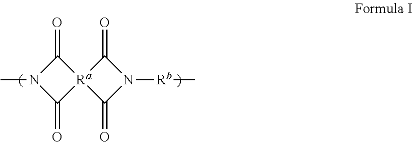

wherein:
R^{a} is a quadrivalent organic group derived from two or more acid dianhydrides wherein at least one of the acid dianhydrides is an aliphatic dianhydride and R^{b} is a divalent organic group derived from one or more diamines;
   such that:
the in-plane coefficient of thermal expansion (CTE) is less than 40 ppm/° C. between 50° C. and 250° C.;
the glass transition temperature (T_{g}) is greater than 300° C. for a polyimide film cured at a temperature above 300° C.;
the 1% TGA weight loss temperature is greater than 350° C.;
the tensile modulus is greater than 5 GPa;
the elongation to break is greater than 5%;
the tensile strength is greater than 100 MPa;
the transmittance at 308 nm is approximately 0%;
the transmittance at 355 nm is less than 1%;
the transmittance at 360 nm is greater than 5%;
the transmittance at 370 nm is greater than 10%;
the transmittance at 400 nm is greater than 40%;
the transmittance at 430 nm is greater than 80%;
the transmittance at 450 nm is greater than 85%;
the transmittance at 550 nm is greater than or equal to 88%;
the optical retardation at 633 nm is less than 300 nm for a 10-micron film;
the birefringence at 633 nm is less than 0.0300; and
b* is less than 3.0.

There is further provided a method for preparing a polyimide film, said method selected from the group consisting of a thermal method and a modified-thermal method, wherein the thermal method comprises the following steps in order:
coating one or more of the polyamic acid solutions disclosed herein onto a matrix;
soft-baking the coated matrix;
treating the soft-baked, coated matrix at a plurality of pre-selected temperatures for a plurality of pre-selected time intervals;
   whereby the polyimide film exhibits:
an in-plane coefficient of thermal expansion (CTE) that is less than 40 ppm/° C. between 50° C. and 250° C.;
a glass transition temperature (T_{g}) that is greater than 300° C. for a polyimide film cured at a temperature above 300° C.;
a 1% TGA weight loss temperature that is greater than 350° C.;
a tensile modulus that is greater than 5 GPa;
an elongation to break that is greater than 5%;
a tensile strength that is greater than 100 MPa;
a transmittance at 308 nm that is approximately 0%;
a transmittance at 355 nm that is less than 1%;
a transmittance at 360 nm that is greater than 5%;
the transmittance at 370 nm is greater than 10%;
a transmittance at 400 nm that is greater than 40%;
a transmittance at 430 nm that is greater than 80%;
a transmittance at 450 nm that is greater than 85%;
a transmittance at 550 nm that is greater than or equal to 88%;
an optical retardation at 633 nm that is less than 300 nm for a 10-micron film;
a birefringence at 633 nm that is less than 0.0300; and
a b* that is less than 3.0; and
   wherein the modified-thermal method comprises the following steps in order:
coating one or more of the polyamic acid solutions disclosed herein, and one or more conversion catalysts, onto a matrix;
soft-baking the coated matrix;
treating the soft-baked, coated matrix at a plurality of pre-selected temperatures for a plurality of pre-selected time intervals;
   such that the maximum of the preselected temperatures is less than that which would be preselected for a polyamic acid solution that does not contain one or more conversion catalysts.

There is further provided a flexible replacement for glass in an electronic device wherein the flexible replacement for glass is a polyimide film having the repeat unit of Formula I

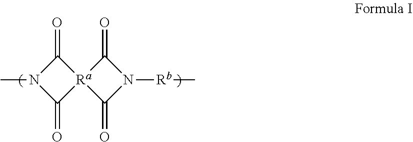

wherein R^{a} is a quadrivalent organic group derived from two or more acid dianhydrides wherein at least one of the acid dianhydrides is an aliphatic dianhydride and R^{b} is a divalent organic group derived from one or more diamines as disclosed herein.

There is further provided an organic electronic device, such as an OLED, wherein the organic electronic device contains a flexible replacement for glass as disclosed herein.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes an illustration of one example of a polyimide film that can act as a flexible replacement for glass.

FIG. 2 includes an illustration of one example of an electronic device that includes a flexible replacement for glass.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

There is provided a solution containing a polyamic acid in a high-boiling, aprotic solvent; wherein the polyamic acid comprises two or more tetracarboxylic acid components and one or more diamine components; and wherein at least one of the tetracarboxylic acid components is a quadrivalent organic group derived from an aliphatic dianhydride; as described in detail below.

There is further provided one or more polyimide films whose repeat units have the structure in Formula I.

There is further provided one or more methods for preparing a polyimide film wherein the polyimide film has the repeat units of Formula I.

There is further provided a flexible replacement for glass in an electronic device wherein the flexible replacement for glass is a polyimide film having the repeat units of Formula I.

There is further provided an electronic device having at least one layer comprising a polyimide film having the repeat units of Formula I.

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by the Polyamic Acid Solution Composition, the Polyimide Films Having the Repeat Unit Structure in Formula I, the Methods for Preparing the Polyimide Films, the Flexible Replacement for Glass in an Electronic Device, the Electronic Device, and finally Examples.

### 1. Definitions and Clarification of Terms

Before addressing details of embodiments described below, some terms are defined or clarified.

As used in the “Definitions and Clarification of Terms”, R, R^{a}, R^{b}, R′, R″ and any other variables are generic designations and may be the same as or different from those defined in the formulas.

The term “alignment layer” is intended to mean a layer of organic polymer in a liquid-crystal device (LCD) that aligns the molecules closest to each plate as a result of its being rubbed onto the LCD glass in one preferential direction during the LCD manufacturing process.

As used herein, the term “alkyl” includes branched and straight-chain saturated aliphatic hydrocarbon groups. Unless otherwise indicated, the term is also intended to include cyclic groups. Examples of alkyl groups include methyl, ethyl, propyl, isopropyl, isobutyl, secbutyl, tertbutyl, pentyl, isopentyl, neopentyl, cyclopentyl, hexyl, cyclohexyl, isohexyl and the like. The term “alkyl” further includes both substituted and unsubstituted hydrocarbon groups. In some embodiments, the alkyl group may be mono-, di- and tri-substituted. One example of a substituted alkyl group is trifluoromethyl. Other substituted alkyl groups are formed from one or more of the substituents described herein. In certain embodiments alkyl groups have 1 to 20 carbon atoms. In other embodiments, the group has 1 to 6 carbon atoms. The term is intended to include heteroalkyl groups. Heteroalkyl groups may have from 1-20 carbon atoms.

The term “aprotic” refers to a class of solvents that lack an acidic hydrogen atom and are therefore incapable of acting as hydrogen donors. Common aprotic solvents include alkanes, carbon tetrachloride (CCl4), benzene, dimethyl formamide (DMF), N-methyl-2-Pyrrolidone (NMP), dimethylacetamide (DMAc), and many others.

The term “aromatic compound” is intended to mean an organic compound comprising at least one unsaturated cyclic group having 4n+2 delocalized pi electrons. The term is intended to encompass both aromatic compounds having only carbon and hydrogen atoms, and heteroaromatic compounds wherein one or more of the carbon atoms within the cyclic group has been replaced by another atom, such as nitrogen, oxygen, sulfur, or the like.

The term “aryl” or “aryl group” means a moiety derived from an aromatic compound. A group “derived from” a compound, indicates the radical formed by removal of one or more hydrogen (“H”) or deuterium (“D”). The aryl group may be a single ring (monocyclic) or have multiple rings (bicyclic, or more) fused together or linked covalently. A “hydrocarbon aryl” has only carbon atoms in the aromatic ring(s). A “heteroaryl” has one or more heteroatoms in at least one aromatic ring. In some embodiments, hydrocarbon aryl groups have 6 to 60 ring carbon atoms; in some embodiments, 6 to 30 ring carbon atoms. In some embodiments, heteroaryl groups have from 4-50 ring carbon atoms; in some embodiments, 4-30 ring carbon atoms.

The term “alkoxy” is intended to mean the group —OR, where R is alkyl.

The term “aryloxy” is intended to mean the group —OR, where R is aryl.

Unless otherwise indicated, all groups can be substituted or unsubstituted. An optionally substituted group, such as, but not limited to, alkyl or aryl, may be substituted with one or more substituents which may be the same or different. Suitable substituents include D, alkyl, aryl, nitro, cyano, —N(R′)(R″), halo, hydroxy, carboxy, alkenyl, alkynyl, cycloalkyl, heteroaryl, alkoxy, aryloxy, heteroaryloxy, alkoxycarbonyl, perfluoroalkyl, perfluoroalkoxy, arylalkyl, silyl, siloxy, siloxane, thioalkoxy, —S(O)₂—, —C(═O)—N(R′)(R″), (R′)(R″)N-alkyl, (R′)(R″)N-alkoxyalkyl, (R′)(R″)N-alkylaryloxyalkyl, —S(O)ₛ-aryl (where s=0-2) or —S(O)ₛ-heteroaryl (where s=0-2). Each R′ and R″ is independently an optionally substituted alkyl, cycloalkyl, or aryl group. R′ and R″, together with the nitrogen atom to which they are bound, can form a ring system in certain embodiments. Substituents may also be crosslinking groups. Any of the preceding groups with available hydrogens, may also be deuterated.

The term “amine” is intended to mean a compound that contains a basic nitrogen atom with a lone pair, where “lone pair” refers to a set of two valence electrons that are not shared with another atom. The term “amino” refers to the functional group —NH₂, —NHR, or —NR₂, where R is the same or different at each occurrence and can be an alkyl group or an aryl group. The term “diamine” is intended to mean a compound that contains two basic nitrogen atoms with associated lone pairs. The term “aromatic diamine” is intended to mean an aromatic compound having two amino groups. The term “bent diamine” is intended to mean a diamine wherein the two basic nitrogen atoms and associated lone pairs are asymmetrically disposed about the center of symmetry of the corresponding compound or functional group, e.g. m-phenylenediamine:

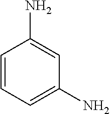

The term “aromatic diamine component” is intended to mean the divalent moiety bonded to the two amino groups in an aromatic diamine compound. The aromatic diamine component is derived from an aromatic diamine compound. The aromatic diamine component may also be described as being made from an aromatic diamine compound.

The term “b*” is intended to mean the b* axis in the CIELab Color Space that represents the yellow/blue opponent colors. Yellow is represented by positive b* values, and blue is represented by negative b* values. Measured b* values may be affected by solvent, particularly since solvent choice may affect color measured on materials exposed to high-temperature processing conditions. This may arise as the result of inherent properties of the solvent and/or properties associated with low levels of impurities contained in various solvents. Particular solvents are often preselected to achieve desired b* values for a particular application.

The term “birefringence” is intended to mean the difference in the refractive index in different directions in a polymer film or coating. This term usually refers to the difference between the x- or y-axis (in-plane) and the z-axis (out-of-plane) refractive indices.

The term “charge transport,” when referring to a layer, material, member, or structure is intended to mean such layer, material, member, or structure facilitates migration of such charge through the thickness of such layer, material, member, or structure with relative efficiency and small loss of charge. Hole transport materials facilitate positive charge; electron transport materials facilitate negative charge. Although light-emitting materials may also have some charge transport properties, the term “charge transport layer, material, member, or structure” is not intended to include a layer, material, member, or structure whose primary function is light emission.

The term “compound” is intended to mean an electrically uncharged substance made up of molecules that further include atoms, wherein the atoms cannot be separated from their corresponding molecules by physical means without breaking chemical bonds. The term is intended to include oligomers and polymers.

The term “crosslinkable group” or “crosslinking group” is intended to mean a group on a compound or polymer chain than can link to another compound or polymer chain via thermal treatment, use of an initiator, or exposure to radiation, where the link is a covalent bond. In some embodiments, the radiation is UV or visible. Examples of crosslinkable groups include, but are not limited to vinyl, acrylate, perfluorovinylether, 1-benzo-3,4-cyclobutane, o-quinodimethane groups, siloxane, cyanate groups, cyclic ethers (epoxides), internal alkenes (e.g., stillbene) cycloalkenes, and acetylenic groups.

The term “linear coefficient of thermal expansion (CTE or α)” is intended to mean the parameter that defines the amount which a material expands or contracts as a function of temperature. It is expressed as the change in length per degree Celsius and is generally expressed in units of μm/m/° C. or ppm/° C.

α=(ΔL/L₀)/ΔT

Measured CTE values disclosed herein are made via known methods during the second heating scan between 50° C. and 250° C. The understanding of the relative expansion/contraction characteristics of materials can be an important consideration in the fabrication and/or reliability of electronic devices.

The term “dopant” is intended to mean a material, within a layer including a host material, that changes the electronic characteristic(s) or the targeted wavelength(s) of radiation emission, reception, or filtering of the layer compared to the electronic characteristic(s) or the wavelength(s) of radiation emission, reception, or filtering of the layer in the absence of such material.

The term “electroactive” as it refers to a layer or a material, is intended to indicate a layer or material which electronically facilitates the operation of the device. Examples of electroactive materials include, but are not limited to, materials which conduct, inject, transport, or block a charge, where the charge can be either an electron or a hole, or materials which emit radiation or exhibit a change in concentration of electron-hole pairs when receiving radiation. Examples of inactive materials include, but are not limited to, planarization materials, insulating materials, and environmental barrier materials.

The term “tensile elongation” or “tensile strain” is intended to mean the percentage increase in length that occurs in a material before it breaks under an applied tensile stress. It can be measured, for example, by ASTM Method D882.

The prefix “fluoro” is intended to indicate that one or more hydrogens in a group have been replaced with fluorine.

The term “glass transition temperature (or T_{g})” is intended to mean the temperature at which a reversible change occurs in an amorphous polymer or in amorphous regions of a semi crystalline polymer where the material changes suddenly from a hard, glassy, or brittle state to one that is flexible or elastomeric. Microscopically, the glass transition occurs when normally-coiled, motionless polymer chains become free to rotate and can move past each other. T_{g}'s may be measured using differential scanning calorimetry (DSC), thermo-mechanical analysis (TMA), or dynamic-mechanical analysis (DMA), or other methods.

The prefix “hetero” indicates that one or more carbon atoms have been replaced with a different atom. In some embodiments, the heteroatom is O, N, S, or combinations thereof.

The term “host material” is intended to mean a material to which a dopant is added. The host material may or may not have electronic characteristic(s) or the ability to emit, receive, or filter radiation. In some embodiments, the host material is present in higher concentration.

The term “isothermal weight loss” is intended to mean a material's property that is directly related to its thermal stability. It is generally measured at a constant temperature of interest via thermogravimetric analysis (TGA). Materials that have high thermal stability generally exhibit very low percentages of isothermal weight loss at the required use or processing temperature for the desired period of time and can therefore be used in applications at these temperatures without significant loss of strength, outgassing, and/or change in structure.

The term “liquid composition” is intended to mean a liquid medium in which a material is dissolved to form a solution, a liquid medium in which a material is dispersed to form a dispersion, or a liquid medium in which a material is suspended to form a suspension or an emulsion.

The term “matrix” is intended to mean a foundation on which one or more layers is deposited in the formation of, for example, an electronic device. Non-limiting examples include glass, silicon, and others.

The term “1% TGA Weight Loss” is intended to mean the temperature at which 1% of the original polymer weight is lost due to decomposition (excluding absorbed water).

The term “optical retardation” is intended to mean the difference between the average in-plane refractive index and the out-of-plane refractive index, this difference then being multiplied by the thickness of the film or coating.

The term “organic electronic device” or sometimes “electronic device” is herein intended to mean a device including one or more organic semiconductor layers or materials.

The term “particle content” is intended to mean the number or count of insoluble particles that is present in a solution. Measurements of particle content can be made on the solutions themselves or on finished materials (pieces, films, etc.) prepared from those films. A variety of optical methods can be used to assess this property.

The term “photoactive” refers to a material or layer that emits light when activated by an applied voltage (such as in a light emitting diode or chemical cell), that emits light after the absorption of photons (such as in down-converting phosphor devices), or that responds to radiant energy and generates a signal with or without an applied bias voltage (such as in a photodetector or a photovoltaic cell).

The term “polyamic acid solution” refers to a solution of a polymer containing amic acid units that have the capability of intramolecular cyclization to form imide groups.

The term “polyimide” refers to condensation polymers derived from bifunctional carboxylic acid anhydrides and primary diamines. They contain the imide structure —CO—NR—CO— as a linear or heterocyclic unit along the main chain of the polymer backbone.

The term “quadrivalent” is intended to mean an atom that has four electrons available for covalent chemical bonding and can therefore form four covalent bonds with other atoms.

The term “satisfactory,” when regarding a materials property or characteristic, is intended to mean that the property or characteristic fulfills all requirements/demands for the material in-use. For example, an isothermal weight loss of less than 1% at 400° C. for 3 hours in nitrogen can be viewed as a non-limiting example of a “satisfactory” property in the context of the polyimide films disclosed herein.

The term “soft-baking” is intended to mean a process commonly used in electronics manufacture wherein coated materials are heated to drive off solvents and solidify a film. Soft-baking is commonly performed on a hot plate or in exhausted oven at temperatures between 90° C. and 110° C. as a preparation step for subsequent thermal treatment of coated layers or films.

The term “substrate” refers to a base material that can be either rigid or flexible and may include one or more layers of one or more materials, which can include, but are not limited to, glass, polymer, metal or ceramic materials or combinations thereof. The substrate may or may not include electronic components, circuits, or conductive members.

The term “siloxane” refers to the group R₃SiOR₂Si—, where R is the same or different at each occurrence and is H, D, C1-20 alkyl, deuterated alkyl, fluoroalkyl, aryl, or deuterated aryl. In some embodiments, one or more carbons in an R alkyl group are replaced with Si. A deuterated siloxane group is one in which one or more R groups are deuterated.

The term “siloxy” refers to the group R₃SiO—, where R is the same or different at each occurrence and is H, D, C1-20 alkyl, deuterated alkyl, fluoroalkyl, aryl, or deuterated aryl. A deuterated siloxy group is one in which one or more R groups are deuterated.

The term “silyl” refers to the group R₃Si—, where R is the same or different at each occurrence and is H, D, C1-20 alkyl, deuterated alkyl, fluoroalkyl, aryl, or deuterated aryl. In some embodiments, one or more carbons in an R alkyl group are replaced with Si. A deuterated silyl group is one in which one or more R groups are deuterated.

The term “coating” is intended to mean a layer of any substance spread over a surface. It can also refer to the process of applying the substance to a surface. The term “spin coating” is intended to mean a particular process used to deposit uniform thin films onto flat substrates. Generally, in “spin coating,” a small amount of coating material is applied on the center of the substrate, which is either spinning at low speed or not spinning at all. The substrate is then rotated at specified speeds in order to spread the coating material uniformly by centrifugal force.

The term “laser particle counter test” refers to a method used to assess the particle content of polyamic acid and other polymeric solutions whereby a representative sample of a test solution is spin coated onto a 5″ silicon wafer and soft baked/dried. The film thus prepared is evaluated for particle content by any number of standard measurement techniques. Such techniques include laser particle detection and others known in the art.

The term “tensile modulus” is intended to mean the measure of the stiffness of a solid material that defines the initial relationship between the stress (force per unit area) and the strain (proportional deformation) in a material like a film. Commonly used units are giga pascals (GPa).

The term “tensile strength” is intended to mean the measure of the maximum stress that a material can withstand while being stretched or pulled before breaking. In contrast to “tensile modulus,” which measures how much a material deforms elastically per unit tensile stress applied, the “tensile strength” of a material is the maximum amount of tensile stress that it can take before failure. Commonly used units are mega pascals (MPa).

The term “tensile elongation” is intended to mean the percentage increase in length that occurs in a material before it breaks under an applied tensile stress. It can be measured, for example, by ASTM Method D882 and is a unitless quantity.

The term “tetracarboxylic acid component” is intended to mean the quadrivalent moiety bonded to four carboxy groups in a tetracarboxylic acid compound. The tetracarboxylic acid compound can be a tetracarboxylic acid, a tetracarboxylic acid monoanhydride, a tetracarboxylic acid dianhydride, a tetracarboxylic acid monoester, or a tetracarboxylic acid diester. The tetracarboxylic acid component is derived from a tetracarboxylic acid compound. The tetracarboxylic acid component may also be described as being made from a tetracarboxylic acid compound.

The term “transparent” or “transparency” refers to the physical property of a material whereby light is allowed to pass through the material without being scattered. It can be true that materials exhibiting high transparency also exhibit low optical retardation and/or low birefringence.

The term “transmittance” refers to the percentage of light of a given wavelength impinging on a film that passes through the film so as to be present or detectable on the other side. Light transmittance measurements in the visible region (380 nm to 800 nm) are particularly useful for characterizing film-color characteristics that are most important for understanding the properties-in-use of the polyimide films disclosed herein. Additionally, radiation of certain wavelengths is often used in the production of films for use in organic electronic devices like OLEDS so that additional “transmittance” criteria are specified. After a display is constructed, for example, a laser lift-off process is used to remove a polyimide film from the glass onto which it was cast. The laser wavelength commonly used for this process is either 308 nm or 355 nm. It is therefore desirable for polyimide films in the current context to have near-zero transmittance at these wavelengths. Further, during display-device construction some process steps may be accomplished using the process of photolithography; wherein a photopolymer is exposed through a glass substrate and the polyimide coating. Given that photolithography radiation commonly has a wavelength of 365 nm, it is desirable for polyimide films in the current context to have at least some transmittance at this wavelength (typically at least 15%) to enable adequate photopolymer exposure.

The term “yellowness index (YI)” refers to the magnitude of yellowness relative to a standard. A positive value of YI indicates the presence, and magnitude, of a yellow color. Materials with a negative YI appear bluish. It should also be noted, particularly for polymerization and/or curing processes run at high temperatures, that YI can be solvent dependent. The magnitude of color introduced using DMAC as a solvent, for example, may be different than that introduced using NMP as a solvent. This may arise as the result of inherent properties of the solvent and/or properties associated with low levels of impurities contained in various solvents. Particular solvents are often preselected to achieve desired YI values for a particular application.

In a structure where a substituent bond passes through one or more rings as shown below,

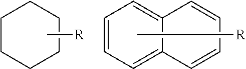

it is meant that the substituent R may be bonded at any available position on the one or more rings.

The phrase “adjacent to,” when used to refer to layers in a device, does not necessarily mean that one layer is immediately next to another layer. On the other hand, the phrase “adjacent R groups,” is used to refer to R groups that are next to each other in a chemical formula (i.e., R groups that are on atoms joined by a bond). Exemplary adjacent R groups are shown below:

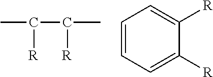

In this specification, unless explicitly stated otherwise or indicated to the contrary by the context of usage, where an embodiment of the subject matter hereof is stated or described as comprising, including, containing, having, being composed of or being constituted by or of certain features or elements, one or more features or elements in addition to those explicitly stated or described may be present in the embodiment. An alternative embodiment of the disclosed subject matter hereof, is described as consisting essentially of certain features or elements, in which embodiment features or elements that would materially alter the principle of operation or the distinguishing characteristics of the embodiment are not present therein. A further alternative embodiment of the described subject matter hereof is described as consisting of certain features or elements, in which embodiment, or in insubstantial variations thereof, only the features or elements specifically stated or described are present.

Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### 2. Polyamic Acid Solution Composition

There is provided a solution containing a polyamic acid in a high-boiling, aprotic solvent; wherein the polyamic acid comprises two or more tetracarboxylic acid components and one or more diamine components; and wherein at least one of the tetracarboxylic acid components is a quadrivalent organic group derived from an aliphatic dianhydride.

The aliphatic portion of the tetracarboxylic acid component of the polyamic acid solution is made from the corresponding aliphatic dianhydride monomers, where the aliphatic dianhydride monomers are selected from the group consisting of cyclobutane dianhydride (CBDA); 3-(carboxymethyl)-1,2,4-cyclopentanetricarboxylic acid 1,4:2,3-dianhydride; bicyclo[2.2.2]oct-7-ene-2,3,5,6-tetracarboxylic dianhydride; 1,2,3,4-cyclopentanetetracarboxylic dianhydride; 1,2,4,5-cyclohexane-tetracarboxylic dianhydride; 1,2,3,4-tetramethyl-1,2,3,4-cyclobutanetetracarboxylic dianhydride; 1,3-dimethyl-1,2,3,4-cyclobutanetetracarboxylic acid dianhydride; tricyclo[6.4.0.02,7]dodecane-1,8:2,7-tetracarboxylic dianhydride; meso-butane-1,2,3,4-tetracarboxylic dianhydride; 4-(2,5-dioxotetrahydrofuran-3-yl)-1,2,3,4-tetrahydronaphthalene-1,2-dicarboxylic anhydride; 5-(2,5-dioxotetrahydrofuryl)-3-methyl-3-cyclohexene-1,2-dicarboxylic anhydride; and the like and combinations thereof.

The aliphatic dianhydrides disclosed herein may optionally be substituted with groups that are known in the art including alkyl, aryl, nitro, cyano, —N(R′)(R″), halo, hydroxy, carboxy, alkenyl, alkynyl, cycloalkyl, heteroaryl, alkoxy, aryloxy, heteroaryloxy, alkoxycarbonyl, perfluoroalkyl, perfluoroalkoxy, arylalkyl, silyl, siloxy, siloxane, thioalkoxy, —S(O)₂—, —C(═O)—N(R′)(R″), (R′)(R″)N-alkyl, (R′)(R″)N-alkoxyalkyl, (R′)(R″)N-alkylaryloxyalkyl, —S(O)ₛ-aryl (where s=0-2) or —S(O)ₛ-heteroaryl (where s=0-2). Each R′ and R″ is independently an optionally substituted alkyl, cycloalkyl, or aryl group. R′ and R″, together with the nitrogen atom to which they are bound, can form a ring system in certain embodiments. Substituents may also be crosslinking groups.

The aromatic portion of the tetracarboxylic acid component of the polyamic acid solution is made from the corresponding aromatic dianhydride monomers, where the aromatic dianhydride monomers are selected from the group consisting of 4,4′-(hexafluoroisopropylidene) diphthalic anhydride (6FDA); 4,4′-oxydiphthalic dianhydride (ODPA); pyromellitic dianhydride (PMDA); 3,3′,4,4′-biphenyltetracarboxylic dianhydride (BPDA); asymmetric 2,3,3′,4′-biphenyltetracarboxylic dianhydride (a-BPDA); 3,3′,4,4′-benzophenone tetracarboxylic dianhydride (BTDA); 3,3′,4,4′-diphenylsulfone tetracarboxylic dianhydrides (DSDA); 4-(2,5-dioxotetrahydrofuran-3-yl)-1,2,3,4-tetrahydronapthalene-1,2-dicarboyxlic anhydride (DTDA); 4,4′-bisphenol A dianhydride (BPADA); and the like and combinations thereof.

The aromatic dianhydrides disclosed herein may optionally be substituted with groups that are known in the art including alkyl, aryl, nitro, cyano, —N(R′)(R″), halo, hydroxy, carboxy, alkenyl, alkynyl, cycloalkyl, heteroaryl, alkoxy, aryloxy, heteroaryloxy, alkoxycarbonyl, perfluoroalkyl, perfluoroalkoxy, arylalkyl, silyl, siloxy, siloxane, thioalkoxy, —S(O)₂—, —C(═O)—N(R′)(R″), (R′)(R″)N-alkyl, (R′)(R″)N-alkoxyalkyl, (R′)(R″)N-alkylaryloxyalkyl, —S(O)ₛ-aryl (where s=0-2) or —S(O)ₛ-heteroaryl (where s=0-2). Each R′ and R″ is independently an optionally substituted alkyl, cycloalkyl, or aryl group. R′ and R″, together with the nitrogen atom to which they are bound, can form a ring system in certain embodiments. Substituents may also be crosslinking groups.

The diamine components result from the corresponding diamine monomers which are selected from the group consisting of p-phenylenediamine (PPD); 2,2′-bis(trifluoromethyl) benzidine (TFMB); m-phenylenediamine (MPD); 4,4′-oxydianiline (4,4′-ODA), 3,4′-oxydianiline (3,4′-ODA); 2,2-bis(3-amino-4-hydroxyphenyl) hexafluoropropane (BAHFP); 1,3-bis(3-aminophenoxy) benzene (m-BAPB), 4,4′-bis(4-aminophenoxy) biphenyl (p-BAPB); 2,2-bis(3-aminophenyl) hexafluoropropane (BAPF); bis[4-(3-aminophenoxy)phenyl] sulfone (m-BAPS); 2,2-bis[4-(4-aminophenoxy)phenyl] sulfone (p-BAPS); m-xylylenediamine (m-XDA); 2,2-bis(3-amino-4-methylphenyl) hexafluoropropane (BAMF); 1,3-bis(aminoethyl) cyclohexane (m-CHDA); 1,4-bis(aminomethyl) cyclohexane (p-CHDA); 1,3-cyclohexanediamine; trans 1,4-damino cyclohexane; and the like and combinations thereof.

The diamine components disclosed herein may optionally be substituted with groups that are known in the art including alkyl, aryl, nitro, cyano, —N(R′)(R″), halo, hydroxy, carboxy, alkenyl, alkynyl, cycloalkyl, heteroaryl, alkoxy, aryloxy, heteroaryloxy, alkoxycarbonyl, perfluoroalkyl, perfluoroalkoxy, arylalkyl, silyl, siloxy, siloxane, thioalkoxy, —S(O)₂—, —C(═O)—N(R′)(R″), (R′)(R″)N-alkyl, (R′)(R″)N-alkoxyalkyl, (R′)(R″)N-alkylaryloxyalkyl, —S(O)ₛ-aryl (where s=0-2) or —S(O)ₛ-heteroaryl (where s=0-2). Each R′ and R″ is independently an optionally substituted alkyl, cycloalkyl, or aryl group. R′ and R″, together with the nitrogen atom to which they are bound, can form a ring system in certain embodiments. Substituents may also be crosslinking groups.

High-boiling polar aprotic solvents are selected from the group consisting of N-methyl-2-Pyrrolidone (NMP), dimethyl acetamide (DMAc), dimethyl sulfoxide (DMSO), dimethyl formamide (DMF), butyrolactone, dibutyl carbitol, butyl carbitol acetate, diethylene glycol monoethyl ether acetate, propylene glycol monomethyl ether acetate and the like and combinations thereof.

In some embodiments, the polyamic acid contains two tetracarboxylic acid components.

In some embodiments, the polyamic acid contains three tetracarboxylic acid components.

In some embodiments, the polyamic acid contains four tetracarboxylic acid components.

In some embodiments, the polyamic acid contains five tetracarboxylic acid components.

In some embodiments, the polyamic acid contains 6 or more tetracarboxylic acid components.

In some embodiments, one of the tetracarboxylic acid components is a quadrivalent organic group derived from an aliphatic dianhydride.

In some embodiments, two of the tetracarboxylic acid components are quadrivalent organic groups derived from aliphatic dianhydrides.

In some embodiments, three or more of the tetracarboxylic acid components are quadrivalent organic groups derived from aliphatic dianhydrides.

In some embodiments, the tetracarboxylic acid component that is a quadrivalent organic group derived from an aliphatic dianhydride is derived from cyclobutane dianhydride (CBDA).

In some embodiments, the tetracarboxylic acid component that is a quadrivalent organic group derived from an aliphatic dianhydride is derived from 3-(carboxymethyl)-1,2,4-cyclopentanetricarboxylic acid 1,4:2,3-dianhydride.

In some embodiments, the tetracarboxylic acid component that is a quadrivalent organic group derived from an aliphatic dianhydride is derived from bicyclo [2.2.2]oct-7-ene-2,3,5,6-tetracarboxylic dianhydride.

In some embodiments, the tetracarboxylic acid component that is a quadrivalent organic group derived from an aliphatic dianhydride is derived from 1,2,3,4-cyclopentanetetracarboxylic dianhydride.

In some embodiments, the tetracarboxylic acid component that is a quadrivalent organic group derived from an aliphatic dianhydride is derived from 1,2,4,5-cyclohexane-tetracarboxylic dianhydride.

In some embodiments, the tetracarboxylic acid component that is a quadrivalent organic group derived from an aliphatic dianhydride is derived from 1,2,3,4-tetramethyl-1,2,3,4-cyclobutanetetracarboxylic dianhydride.

In some embodiments, the tetracarboxylic acid component that is a quadrivalent organic group derived from an aliphatic dianhydride is derived from 1,3-dimethyl-1,2,3,4-cyclobutane-tetracarboxylic acid dianhydride.

In some embodiments, the tetracarboxylic acid component that is a quadrivalent organic group derived from an aliphatic dianhydride is derived from tricyclo[6.4.0.02,7]dodecane-1,8:2,7-tetracarboxylic dianhydride.

In some embodiments, the tetracarboxylic acid component that is a quadrivalent organic group derived from an aliphatic dianhydride is meso-butane-1,2,3,4-tetracarboxylic dianhydride.

In some embodiments, the tetracarboxylic acid component that is a quadrivalent organic group derived from an aliphatic dianhydride is derived from 4-(2,5-dioxotetrahydrofuran-3-yl)-1,2,3,4-tetrahydronaphthalene-1,2-dicarboxylic anhydride.

In some embodiments, the tetracarboxylic acid component that is a quadrivalent organic group derived from an aliphatic dianhydride is derived from 5-(2,5-dioxotetrahydrofuryl)-3-methyl-3-cyclohexene-1,2-dicarboxylic anhydride.

In some embodiments, the tetracarboxylic acid component that is a quadrivalent organic group is derived from pyromellitic dianhydride (PMDA).

In some embodiments, the tetracarboxylic acid component that is a quadrivalent organic group is derived from 3,3′,4,4′-biphenyl tetracarboxylic dianhydride (BPDA).

In some embodiments, the tetracarboxylic acid component that is a quadrivalent organic group is derived from asymmetric 2,3,3′,4′-biphenyltetracarboxylic dianhydride (a-BPDA).

In some embodiments, the tetracarboxylic acid component that is a quadrivalent organic group is derived from 4,4′-(hexafluoroisopropylidene) diphthalic anhydride (6FDA).

In some embodiments, the tetracarboxylic acid component that is a quadrivalent organic group is derived from 4,4′-oxydiphthalic dianhydride (ODPA).

In some embodiments, the tetracarboxylic acid component that is a quadrivalent organic group is derived from 3,3′,4,4′-benzophenone tetracarboxylic dianhydride (BTDA).

In some embodiments, the tetracarboxylic acid component that is a quadrivalent organic group is derived from 3,3′,4,4′-diphenylsulfone tetracarboxylic dianhydrides (DSDA).

In some embodiments, the tetracarboxylic acid component that is a quadrivalent organic group is derived from 4-(2,5-dioxotetrahydrofuran-3-yl)-1,2,3,4-tetrahydronapthalene-1,2-dicarboyxlic anhydride (DTDA).

In some embodiments, the tetracarboxylic acid component that is a quadrivalent organic group is derived from 4,4′-bisphenol A dianhydride (BPADA).

In some embodiments, the polyamic acid contains two tetracarboxylic acid components wherein each tetracarboxylic acid component is present in a mole percent between 0.1% and 99.9%.

In some embodiments, the polyamic acid contains three tetracarboxylic acid components wherein each tetracarboxylic acid component is present in a mole percent between 0.1% and 99.9%.

In some embodiments, the polyamic acid contains four tetracarboxylic acid components wherein each tetracarboxylic acid component is present in a mole percent between 0.1% and 99.9%.

In some embodiments, the polyamic acid contains five tetracarboxylic acid components wherein each tetracarboxylic acid component is present in a mole percent between 0.1% and 99.9%.

In some embodiments, the polyamic acid contains six or more tetracarboxylic acid components wherein each tetracarboxylic acid component is present in a mole percent between 0.1% and 99.9%.

In some embodiments, the tetracarboxylic acid component that is a quadrivalent organic group derived from an aliphatic dianhydride is present in a mole percent between 5% and 95%.

In some embodiments, the tetracarboxylic acid component that is a quadrivalent organic group derived from an aliphatic dianhydride is present in a mole percent between 10% and 90%.

In some embodiments, the tetracarboxylic acid component that is a quadrivalent organic group derived from an aliphatic dianhydride is present in a mole percent between 20% and 90%.

In some embodiments, the tetracarboxylic acid component that is a quadrivalent organic group derived from an aliphatic dianhydride is present in a mole percent between 30% and 80%.

In some embodiments, the tetracarboxylic acid component that is a quadrivalent organic group derived from an aliphatic dianhydride is present in a mole percent between 40% and 60%.

In some embodiments, the tetracarboxylic acid component of the polyamic acid solution is a combination of components derived from cyclobutane dianhydride (CBDA), 3,3′,4,4′-biphenyltetracarboxylic dianhydride (BPDA), 4,4′-(hexafluoroisopropylidene) diphthalic anhydride (6FDA), and 4,4′-oxydiphthalic dianhydride (ODPA) wherein the mole percent of CBDA is between 30% and 80% of the total dianhydride, the mole percent of BPDA is between 5% and 50% of the total dianhydride, the mole percent of 6FDA is between 0% and 30% of the total dianhydride, and the mole percent of ODPA is between 0% and 30% of the total dianhydride.

In some embodiments, the tetracarboxylic acid component of the polyamic acid solution is a combination of components derived from cyclobutane dianhydride (CBDA), 3,3′,4,4′-biphenyltetracarboxylic dianhydride (BPDA), 4,4′-(hexafluoroisopropylidene) diphthalic anhydride (6FDA), and 4,4′-oxydiphthalic dianhydride (ODPA) wherein the mole percent of CBDA is between 40% and 70% of the total dianhydride, the mole percent of BPDA is between 10% and 40% of the total dianhydride, the mole percent of 6FDA is between 20% and 30% of the total dianhydride, and the mole percent of ODPA is between 5% and 15% of the total dianhydride.

In some embodiments, the tetracarboxylic acid component of the polyamic acid solution is a combination of components derived from cyclobutane dianhydride (CBDA), 3,3′,4,4′-biphenyltetracarboxylic dianhydride (BPDA), 4,4′-(hexafluoroisopropylidene) diphthalic anhydride (6FDA), and 4,4′-oxydiphthalic dianhydride (ODPA) wherein the mole percent of CBDA is between 50% and 60% of the total dianhydride, the mole percent of BPDA is between 5% and 50% of the total dianhydride, the mole percent of 6FDA is between 5% and 30% of the total dianhydride, and the mole percent of ODPA is between 5% and 30% of the total dianhydride.

In some embodiments, the tetracarboxylic acid component of the polyamic acid solution is a combination of components derived from cyclobutane dianhydride (CBDA), 3,3′,4,4′-biphenyltetracarboxylic dianhydride (BPDA), 4,4′-(hexafluoroisopropylidene) diphthalic anhydride (6FDA), and 4,4′-oxydiphthalic dianhydride (ODPA) wherein the mole percent of CBDA is between 40% and 70% of the total dianhydride, the mole percent of BPDA is between 5% and 50% of the total dianhydride, and the mole percent of 6FDA is between 5% and 30% of the total dianhydride.

In some embodiments, the tetracarboxylic acid component of the polyamic acid solution is a combination of components derived from cyclobutane dianhydride (CBDA), 3,3′,4,4′-biphenyltetracarboxylic dianhydride (BPDA), 4,4′-(hexafluoroisopropylidene) diphthalic anhydride (6FDA), and 4,4′-oxydiphthalic dianhydride (ODPA) wherein the mole percent of CBDA is between 40% and 70% of the total dianhydride, the mole percent of BPDA is between 5% and 50% of the total dianhydride, and the mole percent of ODPA is between 5% and 30% of the total dianhydride.

In some embodiments, the tetracarboxylic acid component of the polyamic acid solution is a combination of components derived from cyclobutane dianhydride (CBDA), 3,3′,4,4′-biphenyltetracarboxylic dianhydride (BPDA), 4,4′-(hexafluoroisopropylidene) diphthalic anhydride (6FDA) wherein the mole percent of CBDA is 70% of the total dianhydride, the mole percent of BPDA is 10% of the total dianhydride, the mole percent of 6FDA is 20% of the total dianhydride.

In some embodiments, the polyamic acid contains one diamine component.

In some embodiments, the polyamic acid contains two diamine components.

In some embodiments, the polyamic acid contains three or more diamine components.

In some embodiments, the diamine component of the polyamic acid is derived from 2,2′-bis(trifluoromethyl) benzidine (TFMB).

In some embodiments, the diamine component of the polyamic acid is derived from p-phenylenediamine (PPD).

In some embodiments, the diamine component of the polyamic acid is derived from m-phenylenediamine (MPD).

In some embodiments, the diamine component of the polyamic acid is derived from 4,4′-oxydianiline (4,4′-ODA).

In some embodiments, the diamine component of the polyamic acid is derived from 3,4′-oxydianiline (3,4′-ODA).

In some embodiments, the diamine component of the polyamic acid is derived from 2,2-bis(3-amino-4-hydroxyphenyl) hexafluoropropane (BAHFP).

In some embodiments, the diamine component of the polyamic acid is derived from 1,3-bis(3-aminophenoxy) benzene (m-BAPB).

In some embodiments, the diamine component of the polyamic acid is derived from 4,4′-bis(4-aminophenoxy) biphenyl (p-BAPB).

In some embodiments, the diamine component of the polyamic acid is derived from 2,2-bis(3-aminophenyl) hexafluoropropane (BAPF).

In some embodiments, the diamine component of the polyamic acid is derived from bis[4-(3-aminophenoxy)phenyl] sulfone (m-BAPS).

In some embodiments, the diamine component of the polyamic acid is derived from 2,2-bis[4-(4-aminophenoxy)phenyl] sulfone (p-BAPS).

In some embodiments, the diamine component of the polyamic acid is derived from m-xylylenediamine (m-XDA).

In some embodiments, the diamine component of the polyamic acid is derived from 2,2-bis(3-amino-4-methylphenyl) hexafluoropropane (BAMF).

In some embodiments, the diamine component of the polyamic acid is derived from 1,3-bis(aminoethyl) cyclohexane (m-CHDA).

In some embodiments, the diamine component of the polyamic acid is derived from 1,4-bis(aminomethyl) cyclohexane (p-CHDA).

In some embodiments, the diamine component of the polyamic acid is derived from 1,3-cyclohexanediamine.

In some embodiments, the diamine component of the polyamic acid is derived from trans 1,4-damino cyclohexane.

In some embodiments, with two or more monomeric diamine components of the polyamic acid, the mole percentages of the two or more monomeric diamine components are each between 0.1% and 99.9%.

In some embodiments, the mole ratio of the tetracarboxylic acid component to the diamine component of the polyamic acid is 50/50.

In some embodiments, the solvent used in the solution is N-methyl-2-Pyrrolidone (NMP).

In some embodiments, the solvent used in the solution is dimethyl acetamide (DMAc).

In some embodiments, the solvent used in the solution is dimethyl formamide (DMF).

In some embodiments, the solvent used in the solution is butyrolactone.

In some embodiments, the solvent used in the solution is dibutyl carbitol.

In some embodiments, the solvent used in the solution is butyl carbitol acetate.

In some embodiments, the solvent used in the solution is diethylene glycol monoethyl ether acetate.

In some embodiments, the solvent used in the solution is propylene glycol monoethyl ether acetate.

In some embodiments, more than one of the high-boiling aprotic solvents identified herein is used in the solution containing the polyamic acid.

In some embodiments, additional cosolvents are used in the solution containing the polyamic acid.

In some embodiments, the solution containing the polyamic acid is <1 weight % polymer in >99 weight % high-boiling polar aprotic solvent.

In some embodiments, the solution containing the polyamic acid is 1-5 weight % polymer in 95-99 weight % high-boiling polar aprotic solvent.

In some embodiments, the solution containing the polyamic acid is 5-10 weight % polymer in 90-95 weight % high-boiling polar aprotic solvent.

In some embodiments, the solution containing the polyamic acid is 10-15 weight % polymer in 85-90 weight % high-boiling polar aprotic solvent.

In some embodiments, the solution containing the polyamic acid is 15-20 weight % polymer in 80-85 weight % high-boiling polar aprotic solvent.

In some embodiments, the solution containing the polyamic acid is 20-25 weight % polymer in 75-80 weight % high-boiling polar aprotic solvent.

In some embodiments, the solution containing the polyamic acid is 25-30 weight % polymer in 70-75 weight % high-boiling polar aprotic solvent.

In some embodiments, the solution containing the polyamic acid is 30-35 weight % polymer in 65-70 weight % high-boiling polar aprotic solvent.

In some embodiments, the solution containing the polyamic acid is 35-40 weight % polymer in 60-65 weight % high-boiling polar aprotic solvent.

In some embodiments, the solution containing the polyamic acid is 40-45 weight % polymer in 55-60 weight % high-boiling polar aprotic solvent.

In some embodiments, the solution containing the polyamic acid is 45-50 weight % polymer in 50-55 weight % high-boiling polar aprotic solvent.

In some embodiments, the solution containing the polyamic acid is 50 weight % polymer in 50 weight % high-boiling polar aprotic solvent.

In some embodiments, the polyamic acid in the solution has a weight average molecular weight (Mw) greater than 100,000 based on gel permeation chromatography with polystyrene standards.

In some embodiments, the polyamic acid in the solution has a weight average molecular weight (Mw) greater than 150,000 based on gel permeation chromatography with polystyrene standards.

In some embodiments, the polyamic acid in the solution has a molecular weight (Mw) greater than 200,000 based on gel permeation chromatography with polystyrene standards.

In some embodiments, the polyamic acid in the solution has a weight average molecular weight (Mw) greater than 250,000 based on gel permeation chromatography with polystyrene standards.

In some embodiments, the polyamic acid in the solution has a weight average molecular weight (Mw) between 150,000 and 225,000 based on gel permeation chromatography with polystyrene standards.

In some embodiments, the polyamic acid in the solution has a weight average molecular weight (Mw) between 160,000 and 220,000 based on gel permeation chromatography with polystyrene standards.

In some embodiments, the polyamic acid in the solution has a weight average molecular weight (Mw) between 170,000 and 200,000 based on gel permeation chromatography with polystyrene standards.

In some embodiments, the polyamic acid in the solution has a weight average molecular weight (Mw) of 180,000 based on gel permeation chromatography with polystyrene standards.

In some embodiments, the polyamic acid in the solution has a weight average molecular weight (Mw) of 190,000 based on gel permeation chromatography with polystyrene standards.

In some embodiments, the polyamic acid in the solution has a weight average molecular weight (Mw) of 200,000 based on gel permeation chromatography with polystyrene standards.

The solutions containing the polyamic acid may be prepared using a variety of available methods with respect to how the components (i.e., the monomers and solvents) are introduced to one another. Numerous variations of producing a polyamic acid solution include:
(a) a method wherein the diamine components and dianhydride components are preliminarily mixed together and then the mixture is added in portions to a solvent while stirring.
(b) a method wherein a solvent is added to a stirring mixture of diamine and dianhydride components (contrary to (a) above).
(c) a method wherein diamines are exclusively dissolved in a solvent and then dianhydrides are added thereto at such a ratio as allowing to control the reaction rate.
(d) a method wherein the dianhydride components are exclusively dissolved in a solvent and then amine components are added thereto at such a ratio to allow control of the reaction rate.
(e) a method wherein the diamine components and the dianhydride components are separately dissolved in solvents and then these solutions are mixed in a reactor.
(f) a method wherein the polyamic acid with excessive amine component and another polyamic acid with excessive dianhydride component are preliminarily formed and then reacted with each other in a reactor, particularly in such a way as to create a non-random or block copolymer.
(g) a method wherein a specific portion of the amine components and the dianhydride components are first reacted and then the residual diamine components are reacted, or vice versa.
(h) a method wherein the components are added in part or in whole in any order to either part or whole of the solvent, also where part or all of any component can be added as a solution in part or all of the solvent.
(i) a method of first reacting one of the dianhydride components with one of the diamine components giving a first polyamic acid. Then reacting the other dianhydride component with the other amine component to give a second polyamic acid. Then combining the amic acids in any one of a number of ways prior to film formation.
   Generally speaking, a solution containing a polyamic acid can be derived from any one of the preparation methods disclosed above.

Further, in some embodiments, the polyimide films and associated materials disclosed herein can be made from other suitable polyimide precursors such as poly(amic ester)s, polyisoimides, and polyamic acid salts. Further, if the polyimide is soluble in suitable coating solvents, it may be provided as an already-imidized polymer dissolved in the suitable coating solvent.

The polyamic acid solutions can optionally further contain any one of a number of additives. Such additives can be: antioxidants, heat stabilizers, adhesion promoters, coupling agents (e.g. silanes), inorganic fillers or various reinforcing agents so long as they do not impact the desired polyimide properties.

The additives can be used in forming the polyimide films and can be specifically chosen to provide important physical attributes to the film. Beneficial properties commonly sought include, but are not limited to, high and/or low modulus, good mechanical elongation, a low coefficient of in-plane thermal expansion (CTE), a low coefficient of humidity expansion (CHE), high thermal stability, and a particular glass transition temperature (T_{g}).

The solutions disclosed herein can then be filtered one or more times so as to reduce the particle content. The polyimide film generated from such a filtered solution can show a reduced number of defects and thereby lead to superior performance in the electronics applications disclosed herein. An assessment of the filtration efficiency can be made by the laser particle counter test wherein a representative sample of the polyamic acid solution is cast onto a 5″ silicon wafer. After soft baking/drying, the film is evaluated for particle content by any number of laser particle counting techniques on instruments that are commercially available and known in the art.

In some embodiments, the solution containing the polyamic acid is prepared and filtered to yield a particle content of less than 40 particles as measured by the laser particle counter test.

In some embodiments, the solution containing the polyamic acid is prepared and filtered to yield a particle content of less than 30 particles as measured by the laser particle counter test.

In some embodiments, the solution containing the polyamic acid is prepared and filtered to yield a particle content of less than 20 particles as measured by the laser particle counter test.

In some embodiments, the solution containing the polyamic acid is prepared and filtered to yield a particle content of less than 10 particles as measured by the laser particle counter test.

In some embodiments, the solution containing the polyamic acid is prepared and filtered to yield particle content of between 2 particles and 8 particles as measured by the laser particle counter test.

In some embodiments, the solution containing the polyamic acid is prepared and filtered to yield particle content of between 4 particles and 6 particles as measured by the laser particle counter test.

Any of the above embodiments for the solution containing the polyamic acid can be combined with one or more of the other embodiments, so long as they are not mutually exclusive. For example, the embodiment in which the tetracarboxylic acid component that is a quadrivalent organic group derived from an aliphatic dianhydride is CBDA can be combined with the embodiment in which the solvent used in the solution is N-methyl-2-Pyrrolidone (NMP). The same is true for the other non-mutually-exclusive embodiments discussed above. The skilled person would understand which embodiments were mutually exclusive and would thus readily be able to determine the combinations of embodiments that are contemplated by the present application.

Exemplary preparations of the solutions containing polyamic acid are given in the examples. Some non-limiting examples of polyamic acid compositions, in terms of mole %, include those in Table 1.

TABLE 1

| | CBDA | BPDA | 6FDA | ODPA | TFMB |
|---|---|---|---|---|---|
| PAA-1 | 20% | 50% | 15% | 15% | 100 |
| PAA-2 | 25% | 40% | 5% | 30% | 100 |
| PAA-3 | 30% | 30% | 30% | 10% | 100 |
| PAA-4 | 35% | 30% | 5% | 30% | 100 |
| PAA-5 | 40% | 30% | 15% | 15% | 100 |
| PAA-6 | 45% | 30% | 25% | 0% | 100 |
| PAA-7 | 50% | 20% | 0% | 30% | 100 |
| PAA-8 | 55% | 20% | 0% | 25% | 100 |
| PAA-9 | 60% | 20% | 10% | 10% | 100 |
| PAA-10 | 65% | 20% | 5% | 10% | 100 |
| PAA-11 | 70% | 10% | 20% | 0% | 100 |
| PAA-12 | 75% | 8% | 7% | 10% | 100 |
| PAA-13 | 80% | 8% | 10% | 2% | 100 |
| PAA-14 | 85% | 5% | 10% | 0% | 100 |
| PAA-15 | 90% | 2% | 0% | 8% | 100 |
| PAA-16 | 90% | 2% | 8% | 0% | 100 |

Overall compositions can also be designated via the notation commonly used in the art. Polyamic acid PAA-1, for example, can be represented as:
CBDA/BPDA/6FDA/ODPA//TFMB 20/50/15/15//100

In some embodiments, the solutions containing a polyamic acid disclosed in Table 1 comprise the polyamic acid and a high-boiling, aprotic solvent.

In some embodiments, the solutions containing a polyamic acid disclosed in Table 1 consist essentially of the polyamic acid and a high-boiling, aprotic solvent.

In some embodiments, the solutions containing a polyamic acid disclosed in Table 1 consist of the polyamic acid and a high-boiling, aprotic solvent.

In some embodiments, the solutions containing polyamic acid disclosed in Table 1 comprise CBDA, BPDA, 6FDA, ODPA, TFMB, and a high-boiling, aprotic solvent.

In some embodiments, the solutions containing polyamic acid disclosed in Table 1 consist of CBDA, BPDA, 6FDA, ODPA, TFMB, and a high-boiling, aprotic solvent.

In some embodiments, the solutions containing polyamic acid disclosed in Table 1 consist essentially of CBDA, BPDA, 6FDA, ODPA, TFMB, and a high-boiling, aprotic solvent.

In some embodiments, the solutions containing polyamic acid disclosed in Table 1 comprise CBDA, BPDA, TFMB, and a high-boiling, aprotic solvent.

In some embodiments, the solutions containing polyamic acid disclosed in Table 1 consist of CBDA, BPDA, TFMB, and a high-boiling, aprotic solvent.

In some embodiments, the solutions containing polyamic acid disclosed in Table 1 consist essentially of CBDA, BPDA, TFMB, and a high-boiling, aprotic solvent.

In some embodiments, the solutions containing polyamic acid disclosed in Table 1 comprise CBDA, BPDA, 6FDA, TFMB, and a high-boiling, aprotic solvent.

In some embodiments, the solutions containing polyamic acid disclosed in Table 1 consist of CBDA, BPDA, 6FDA, TFMB, and a high-boiling, aprotic solvent.

In some embodiments, the solutions containing polyamic acid disclosed in Table 1 consist essentially of CBDA, BPDA, 6FDA, TFMB, and a high-boiling, aprotic solvent.

### 3. Polyimide Film Composition

The solutions containing polyamic acids disclosed herein may be used to generate polyimide films, wherein the polyimide films contain two or more tetracarboxylic acid components and one or more diamine components, wherein at least one of the tetracarboxylic acid components is a quadrivalent organic group derived from an aliphatic dianhydride.

The aliphatic portion of the tetracarboxylic acid component of the polyimide films is made from the corresponding aliphatic dianhydride monomers, where the aliphatic dianhydride monomers are selected from the group consisting of cyclobutane dianhydride (CBDA); 3-(carboxymethyl)-1,2,4-cyclopentanetricarboxylic acid 1,4:2,3-dianhydride; bicyclo[2.2.2]oct-7-ene-2,3,5,6-tetracarboxylic dianhydride; 1,2,3,4-cyclopentanetetracarboxylic dianhydride; 1,2,4,5-cyclohexane-tetracarboxylic dianhydride; 1,2,3,4-tetramethyl-1,2,3,4-cyclobutanetetracarboxylic dianhydride; 1,3-dimethyl-1,2,3,4-cyclobutanetetracarboxylic acid dianhydride; tricyclo[6.4.0.02,7]dodecane-1,8:2,7-tetracarboxylic dianhydride; meso-butane-1,2,3,4-tetracarboxylic dianhydride; 4-(2,5-dioxotetrahydrofuran-3-yl)-1,2,3,4-tetrahydronaphthalene-1,2-dicarboxylic anhydride; 5-(2,5-dioxotetrahydrofuryl)-3-methyl-3-cyclohexene-1,2-dicarboxylic anhydride; and the like and combinations thereof.

The aliphatic dianhydrides disclosed herein may optionally be substituted with groups that are known in the art including alkyl, aryl, nitro, cyano, —N(R′)(R″), halo, hydroxy, carboxy, alkenyl, alkynyl, cycloalkyl, heteroaryl, alkoxy, aryloxy, heteroaryloxy, alkoxycarbonyl, perfluoroalkyl, perfluoroalkoxy, arylalkyl, silyl, siloxy, siloxane, thioalkoxy, —S(O)₂—, —C(═O)—N(R′)(R″), (R′)(R″)N-alkyl, (R′)(R″)N-alkoxyalkyl, (R′)(R″)N-alkylaryloxyalkyl, —S(O)ₛ-aryl (where s=0-2) or —S(O)ₛ-heteroaryl (where s=0-2). Each R′ and R″ is independently an optionally substituted alkyl, cycloalkyl, or aryl group. R′ and R″, together with the nitrogen atom to which they are bound, can form a ring system in certain embodiments. Substituents may also be crosslinking groups.

The aromatic portion of the tetracarboxylic acid component of the polyimide films is made from the corresponding aromatic dianhydride monomers, where the aromatic dianhydride monomers are selected from the group consisting of 4,4′-(hexafluoroisopropylidene) diphthalic anhydride (6FDA); 4,4′-oxydiphthalic dianhydride (ODPA); pyromellitic dianhydride (PMDA); 3,3′,4,4′-biphenyltetracarboxylic dianhydride (BPDA); asymmetric 2,3,3′,4′-biphenyltetracarboxylic dianhydride (a-BPDA); 3,3′,4,4′-benzophenone tetracarboxylic dianhydride (BTDA); 3,3′,4,4′-diphenylsulfone tetracarboxylic dianhydrides (DSDA); 4-(2,5-dioxotetrahydrofuran-3-yl)-1,2,3,4-tetrahydronapthalene-1,2-dicarboyxlic anhydride (DTDA); 4,4′-bisphenol A dianhydride (BPADA); and the like and combinations thereof.

The aromatic dianhydrides disclosed herein may optionally be substituted with groups that are known in the art including alkyl, aryl, nitro, cyano, —N(R′)(R″), halo, hydroxy, carboxy, alkenyl, alkynyl, cycloalkyl, heteroaryl, alkoxy, aryloxy, heteroaryloxy, alkoxycarbonyl, perfluoroalkyl, perfluoroalkoxy, arylalkyl, silyl, siloxy, siloxane, thioalkoxy, —S(O)₂—, —C(═O)—N(R′)(R″), (R′)(R″)N-alkyl, (R′)(R″)N-alkoxyalkyl, (R′)(R″)N-alkylaryloxyalkyl, —S(O)ₛ-aryl (where s=0-2) or —S(O)ₛ-heteroaryl (where s=0-2). Each R′ and R″ is independently an optionally substituted alkyl, cycloalkyl, or aryl group. R′ and R″, together with the nitrogen atom to which they are bound, can form a ring system in certain embodiments. Substituents may also be crosslinking groups.

The diamine components of the polyimide films result from the corresponding diamine monomers which are selected from the group consisting of p-phenylenediamine (PPD); 2,2′-bis(trifluoromethyl) benzidine (TFMB); m-phenylenediamine (MPD); 4,4′-oxydianiline (4,4′-ODA), 3,4′-oxydianiline (3,4′-ODA); 2,2-bis(3-amino-4-hydroxyphenyl) hexafluoropropane (BAHFP); 1,3-bis(3-aminophenoxy) benzene (m-BAPB), 4,4′-bis(4-aminophenoxy) biphenyl (p-BAPB); 2,2-bis(3-aminophenyl) hexafluoropropane (BAPF); bis[4-(3-aminophenoxy)phenyl] sulfone (m-BAPS); 2,2-bis[4-(4-aminophenoxy)phenyl] sulfone (p-BAPS); m-xylylenediamine (m-XDA); 2,2-bis(3-amino-4-methylphenyl) hexafluoropropane (BAMF); 1,3-bis(aminoethyl) cyclohexane (m-CHDA); 1,4-bis(aminomethyl) cyclohexane (p-CHDA); 1,3-cyclohexanediamine; trans 1,4-damino cyclohexane; and the like and combinations thereof.

The diamine components disclosed herein may optionally be substituted with groups that are known in the art including alkyl, aryl, nitro, cyano, —N(R′)(R″), halo, hydroxy, carboxy, alkenyl, alkynyl, cycloalkyl, heteroaryl, alkoxy, aryloxy, heteroaryloxy, alkoxycarbonyl, perfluoroalkyl, perfluoroalkoxy, arylalkyl, silyl, siloxy, siloxane, thioalkoxy, —S(O)₂—, —C(═O)—N(R′)(R″), (R′)(R″)N-alkyl, (R′)(R″)N-alkoxyalkyl, (R′)(R″)N-alkylaryloxyalkyl, —S(O)ₛ-aryl (where s=0-2) or —S(O)ₛ-heteroaryl (where s=0-2). Each R′ and R″ is independently an optionally substituted alkyl, cycloalkyl, or aryl group. R′ and R″, together with the nitrogen atom to which they are bound, can form a ring system in certain embodiments. Substituents may also be crosslinking groups.

In some embodiments, the polyimide film contains two tetracarboxylic acid components.

In some embodiments, the polyimide film contains three tetracarboxylic acid components.

In some embodiments, the polyimide film contains four tetracarboxylic acid components.

In some embodiments, the polyimide film contains five tetracarboxylic acid components.

In some embodiments, the polyimide film contains 6 or more tetracarboxylic acid components.

In some embodiments, one of the tetracarboxylic acid components is a quadrivalent organic group derived from an aliphatic dianhydride.

In some embodiments, two of the tetracarboxylic acid components are quadrivalent organic groups derived from aliphatic dianhydrides.

In some embodiments, three or more of the tetracarboxylic acid components are quadrivalent organic groups derived from aliphatic dianhydrides.

The polyimide films disclosed herein contain the tetracarboxylic acid components and diamine components as disclosed above for the corresponding polyamic acid solutions from which they can be prepared.

Exemplary preparations the polyimide films are given in the examples. Some non-limiting examples of polyimide film compositions, expressed in mole %, include those in Table 2.

TABLE 2

| | CBDA | BPDA | 6FDA | ODPA | TFMB |
|---|---|---|---|---|---|
| PF-1 | 20% | 50% | 15% | 15% | 100 |
| PF-2 | 25% | 40% | 5% | 30% | 100 |
| PF-3 | 30% | 30% | 30% | 10% | 100 |
| PF-4 | 35% | 30% | 5% | 30% | 100 |
| PF-5 | 40% | 30% | 15% | 15% | 100 |
| PF-6 | 45% | 30% | 25% | 0% | 100 |
| PF-7 | 50% | 20% | 0% | 30% | 100 |
| PF-8 | 55% | 20% | 0% | 25% | 100 |
| PF-9 | 60% | 20% | 10% | 10% | 100 |
| PF-10 | 65% | 20% | 5% | 10% | 100 |
| PF-11 | 70% | 10% | 20% | 0% | 100 |
| PF-12 | 75% | 8% | 7% | 10% | 100 |
| PF-13 | 80% | 8% | 10% | 2% | 100 |
| PF-14 | 85% | 5% | 10% | 0% | 100 |
| PF-15 | 90% | 2% | 0% | 8% | 100 |
| PF-16 | 90% | 2% | 8% | 0% | 100 |

Overall compositions can also be designated via the notation commonly used in the art. Polyimide film PF-1, for example, can be represented as:
CBDA/BPDA/6FDA/ODPA//TFMB 20/50/15/15//100

In some embodiments, the polyimide films disclosed in Table 2 comprise the polyimide.

In some embodiments, the polyimide films disclosed in Table 2 consist essentially of the polyimide.

In some embodiments, the polyimide films disclosed in Table 2 consist of the polyimide.

In some embodiments, the polyimide films disclosed in Table 2 comprise CBDA, BPDA, 6FDA, ODPA, and TFMB.

In some embodiments, the polyimide films disclosed in Table 2 consist of CBDA, BPDA, 6FDA, ODPA, and TFMB.

In some embodiments, the polyimide films disclosed in Table 2 consist essentially of CBDA, BPDA, 6FDA, ODPA, and TFMB.

In some embodiments, the polyimide films disclosed in Table 2 comprise CBDA, BPDA, and TFMB.

In some embodiments, the polyimide films disclosed in Table 2 consist of CBDA, BPDA, and TFMB.

In some embodiments, the polyimide films disclosed in Table 2 consist essentially of CBDA, BPDA, and TFMB.

In some embodiments, the polyimide films disclosed in Table 2 comprise CBDA, BPDA, 6FDA, and TFMB.

In some embodiments, the polyimide films disclosed in Table 2 consist of CBDA, BPDA, 6FDA, and TFMB.

In some embodiments, the polyimide films disclosed in Table 2 consist essentially of CBDA, BPDA, 6FDA, and TFMB.

The polyimide films disclosed herein comprise the repeat unit of Formula I

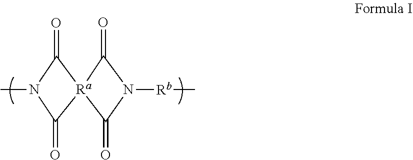

wherein:
R^{a} is a quadrivalent organic group derived from two or more acid dianhydrides wherein at least one of the acid dianhydrides is an aliphatic dianhydride and R^{b} is a divalent organic group derived from one or more diamines;
   such that:
the in-plane coefficient of thermal expansion (CTE) is less than 40 ppm/° C. between 50° C. and 250° C.;
the glass transition temperature (T_{g}) is greater than 300° C. for a polyimide film cured at a temperature above 300° C.;
the 1% TGA weight loss temperature is greater than 350° C.;
the tensile modulus is greater than 5 GPa;
the elongation to break is greater than 5%;
the tensile strength is greater than 100 MPa;
the transmittance at 308 nm is approximately 0%;
the transmittance at 355 nm is less than 1%;
the transmittance at 360 nm is greater than 5%;
the transmittance at 370 nm is greater than 10%;
the transmittance at 400 nm is greater than 40%;
the transmittance at 430 nm is greater than 80%;
the transmittance at 450 nm is greater than 85%;
the transmittance at 550 nm is greater than or equal to 88%;
the optical retardation at 633 nm is less than 300 nm for a 10 micron film;
the birefringence at 633 nm is less than 0.0300; and
b* is less than 3.0.

In some embodiments, the polyimide film has an in-plane coefficient of thermal expansion (CTE) of less than 50 ppm/° C. between 50° C. and 250° C.

In some embodiments, the polyimide film has an in-plane coefficient of thermal expansion (CTE) of less than 40 ppm/° C. between 50° C. and 250° C.

In some embodiments, the polyimide film has an in-plane coefficient of thermal expansion (CTE) of less than 30 ppm/° C. between 50° C. and 250° C.

In some embodiments, the polyimide film has an in-plane coefficient of thermal expansion (CTE) of less than 20 ppm/° C. between 50° C. and 250° C.

In some embodiments, the polyimide film has an in-plane coefficient of thermal expansion (CTE) of less than 10 ppm/° C. between 50° C. and 250° C.

In some embodiments, the polyimide film has an in-plane coefficient of thermal expansion (CTE) of between 10 ppm/° C. and 20 ppm/° C. between 50° C. and 250° C.

In some embodiments, the polyimide film has a glass transition temperature (T_{g}) of greater than 250° C. for a polyimide film cured at a temperature above 300° C.

In some embodiments, the polyimide film has a glass transition temperature (T_{g}) of greater than 275° C. for a polyimide film cured at a temperature above 300° C.

In some embodiments, the polyimide film has a glass transition temperature (T_{g}) of greater than 300° C. for a polyimide film cured at a temperature above 300° C.

In some embodiments, the polyimide film has a glass transition temperature (T_{g}) of greater than 325° C. for a polyimide film cured at a temperature above 300° C.

In some embodiments, the polyimide film has a glass transition temperature (T_{g}) of greater than 350° C. for a polyimide film cured at a temperature above 300° C.

In some embodiments, the polyimide film has a 1% TGA weight loss temperature greater than 300° C.

In some embodiments, the polyimide film has a 1% TGA weight loss temperature greater than 350° C.

In some embodiments, the polyimide film has a 1% TGA weight loss temperature greater than 400° C.

In some embodiments, the polyimide film has a tensile modulus that is greater than 1 GPa.

In some embodiments, the polyimide film has a tensile modulus that is greater than or equal to 3 GPa.

In some embodiments, the polyimide film has a tensile modulus that is between 3 GPa and 5 GPa.

In some embodiments, the polyimide film has a tensile modulus that is greater than 5 GPa.

In some embodiments, the polyimide film has a tensile modulus that is between 3 GPa and 10 GPa.

In some embodiments, the polyimide film has a tensile modulus that is greater than 10 GPa.

In some embodiments, the polyimide film has an elongation to break that is greater than 1%.

In some embodiments, the polyimide film has an elongation to break that is greater than 5%.

In some embodiments, the polyimide film has an elongation to break that is greater than 10%.

In some embodiments, the polyimide film has an elongation to break that is 10%-15%.

In some embodiments, the polyimide film has an elongation to break that is 15%-20%.

In some embodiments, the polyimide film has an elongation to break that is greater than 20%.

In some embodiments, the polyimide film has a tensile strength that is greater than 75 MPa.

In some embodiments, the polyimide film has a tensile strength that is greater than 100 MPa.

In some embodiments, the polyimide film has a tensile strength that is greater than 125 MPa.

In some embodiments, the polyimide film has a tensile strength that is greater than 150 MPa.

In some embodiments, the polyimide film has a transmittance at 308 nm that is less than or equal to 10%.

In some embodiments, the polyimide film has a transmittance at 308 nm that is less than or equal to 5%.

In some embodiments, the polyimide film has a transmittance at 308 nm that is less than or equal to 2%.

In some embodiments, the polyimide film has a transmittance at 308 nm that is equal to 0%.

In some embodiments, the polyimide film has a transmittance at 355 nm that is less than or equal to 5%.

In some embodiments, the polyimide film has a transmittance at 355 nm that is less than or equal to 2%.

In some embodiments, the polyimide film has a transmittance at 355 nm that is less than or equal to 1%.

In some embodiments, the polyimide film has a transmittance at 360 nm that is greater than or equal to 1%.

In some embodiments, the polyimide film has a transmittance at 360 nm that is greater than or equal to 3%.

In some embodiments, the polyimide film has a transmittance at 360 nm that is greater than or equal to 5%.

In some embodiments, the polyimide film has a transmittance at 360 nm that is greater than or equal to 10%.

In some embodiments, the polyimide film has a transmittance at 360 nm that is greater than or equal to 15%.

In some embodiments, the polyimide film has a transmittance at 360 nm that allows efficient photolithography processes exposure processes for the production of electronic devices like those disclosed herein.

In some embodiments, the polyimide film has a transmittance at 370 nm that allows efficient photolithography processes exposure processes for the production of electronic devices like those disclosed herein.

In some embodiments, the polyimide film has a transmittance at 400 nm that is greater than or equal to 30%.

In some embodiments, the polyimide film has a transmittance at 400 nm that is greater than or equal to 40%.

In some embodiments, the polyimide film has a transmittance at 400 nm that is greater than or equal to 50%.

In some embodiments, the polyimide film has a transmittance at 430 nm that is greater than or equal to 60%.

In some embodiments, the polyimide film has a transmittance at 430 nm that is greater than or equal to 70%.

In some embodiments, the polyimide film has a transmittance at 430 nm that is greater than or equal to 80%.

In some embodiments, the polyimide film has a transmittance at 450 nm that is greater than or equal to 70%.

In some embodiments, the polyimide film has a transmittance at 450 nm that is greater than or equal to 80%.

In some embodiments, the polyimide film has a transmittance at 450 nm that is greater than or equal to 90%.

In some embodiments, the polyimide film has a transmittance at 550 nm that is greater than or equal to 75%.

In some embodiments, the polyimide film has a transmittance at 550 nm that is greater than or equal to 85%.

In some embodiments, the polyimide film has a transmittance at 550 nm that is greater than or equal to 90%.

In some embodiments, the polyimide film has an optical retardation that is less than 400 nm for a 10 micron film.

In some embodiments, the polyimide film has an optical retardation that is less than 350 nm for a 10 micron film.

In some embodiments, the polyimide film has an optical retardation that is less than 300 nm for a 10 micron film.

In some embodiments, the polyimide film has an optical retardation that is less than 200 nm for a 10 micron film.

In some embodiments, the polyimide film has a birefringence at 633 nm that is less than 0.0500.

In some embodiments, the polyimide film has a birefringence at 633 nm that is less than 0.0400.

In some embodiments, the polyimide film has a birefringence at 633 nm that is less than 0.0300.

In some embodiments, the polyimide film has a birefringence at 633 nm that is less than 0.0200.

In some embodiments, the polyimide film has a b* that is less than 5.0 when cast from a solvent selected from those disclosed herein.

In some embodiments, the polyimide film has a b* that is less than 4.0 when cast from a solvent selected from those disclosed herein.

In some embodiments, the polyimide film has a b* that is less than 3.0 when cast from a solvent selected from those disclosed herein.

In some embodiments, the polyimide film has a b* that is less than 2.0 when cast from a solvent selected from those disclosed herein.

In some embodiments, the polyimide film has a b* that is less than 1.0 when cast from a solvent selected from those disclosed herein.

The polyimide films disclosed herein generally have thicknesses that are appropriate for a wide variety of electronics end-use applications. These applications include, but are not limited to, those disclosed herein.

In some embodiments, the dry polyimide film thickness is between 5 microns and 25 microns.

In some embodiments, the dry polyimide film thickness is less than 20 microns.

In some embodiments, the dry polyimide film thickness is between 10 microns and 20 microns.

In some embodiments, the dry polyimide film thickness is between 10 microns and 15 microns.

In some embodiments, the dry polyimide film thickness is less than 10 microns.

In some embodiments, the dry polyimide film thickness is between 5 microns and 10 microns.

In some embodiments, the dry polyimide film thickness is less than 5 microns.

Typically, the polyamic acids/polyimides disclosed herein are coated/cured onto a supporting glass substrate to facilitate the processing through the rest of the display making process. At some point in the process as determined by the display maker, the polyimide coating is removed from the supporting glass substrate by a mechanical or laser lift-off process. This separates the polyimide as a film with the deposited display layers from the glass and enables a flexible format.

Any of the above embodiments for the polyimide film can be combined with one or more of the other embodiments, so long as they are not mutually exclusive. For example, the embodiment in which the tetracarboxylic acid component of the polyimide film is cyclobutane dianhydride (CBDA) can be combined with the embodiment in which the glass transition temperature (T_{g}) of the film is greater than 350° C. The same is true for the other non-mutually-exclusive embodiments discussed above. The skilled person would understand which embodiments were mutually exclusive and would thus readily be able to determine the combinations of embodiments that are contemplated by the present application.

The utility of the polyimide films disclosed herein for a wide variety of electronics applications is a direct result of the fact that the properties of such films can be optimized via a number of compositional and synthetic parameters. For example, low in-plane CTE can be achieved by employing rigid rod-like monomers such as BPDA and TFMB to form correspondingly rod-like polyimide polymer chains which preferentially orient in the plane of the film affording low in-plane CTE. Aliphatic dianhydrides such as CBDA can affect properties through the incorporation of aliphatic character to an otherwise all-aromatic polymeric system. For example, the CBDA//TFMB polyimide has the desired percent transmittance at 365 nm but also possesses higher-than-desired percent transmittance at 355 nm and 308 nm. Unfortunately, the increased aliphatic character also decreases the toughness of the polyimide, generally manifested by low tensile modulus and low elongation to break. On the other hand, monomers that contain flexible bridging units such as 6FDA and ODPA tend to afford higher-transparency polyimides due to the electronic and steric effects of the bridging groups, but at the expense of unacceptably high thermal expansion.

Often, it can be difficult to incorporate many of the desired properties for certain electronics applications in one material. For example, the BPDA//TFMB polyimide exhibits low in-plane CTE (<20 ppm/° C.) and good chemical resistance, but exhibits higher than desired yellowness index and b* as well as higher birefringence and optical retardation. While it possesses low percent transmittance at 308 and 355 nm, it also has unacceptably low transmittance at 365 nm. The 6FDA//TFMB or ODPA/TFMB polyimides have improved transparency, lower birefringence, and lower optical retardation; but have a much higher in-plane CTE (>40 ppm/° C.) and may be sensitive to certain solvents used in the display production process. These polyimides also have lower-than-desired percent transmittance at 365 nm due to their all-aromatic structure.

Surprisingly and unexpectedly, the materials disclosed herein demonstrate that certain combinations of these monomers, and the appropriate imidization conditions, can be used to produce polyimide films with an optimum balance of properties for use in electronics applications. For example, partially aliphatic polyimides based on CBDA/BPDA//TFMB with minor amounts of either 6FDA or ODPA can provide the low in-plane CTE and high toughness characteristic of the BPDA//TFMB homopolymer, while delivering near zero transmittance at 355 nm and approximately 15% transmittance at 365 nm. The copolymers also possess high average transparency, low color as defined by b*, with low birefringence and optical retardation.

### 4. Methods for Preparing Polyimide Film

There are provided thermal and modified-thermal methods for preparing a polyimide film. The thermal method comprises the following steps in order: coating a solution containing a polyamic acid comprising two or more tetracarboxylic acid components and one or more diamine components in a high-boiling, aprotic solvent onto a matrix; soft-baking the coated matrix; treating the soft-baked, coated matrix at a plurality of pre-selected temperatures for a plurality of pre-selected time intervals whereby the polyimide film exhibits properties that are satisfactory for use in electronics applications like those disclosed herein.

Generally, polyimide films can be prepared from the corresponding solutions containing polyamic acids by chemical or thermal conversion processes. The polyimide films disclosed herein, particularly when used as flexible replacements for glass in electronic devices, are prepared by thermal conversion or modified-thermal conversion processes, versus chemical conversion processes.

Chemical conversion processes are described in U.S. Pat. Nos. 5,166,308 and 5,298,331 which are incorporated by reference in their entirety. In such processes, conversion chemicals are added to the solutions that contain the polyamic acid. The conversion chemicals found to be useful in the present invention include, but are not limited to, (i) one or more dehydrating agents, such as, aliphatic acid anhydrides (acetic anhydride, etc.) and acid anhydrides; and (ii) one or more catalysts, such as, aliphatic tertiary amines (triethylamine, etc.), tertiary amines (dimethylaniline, etc.) and heterocyclic tertiary amines (pyridine, picoline, isoquinoilne, etc.). The anhydride dehydrating material is typically used in a slight molar excess of the amount of amide acid groups present in the polyamic acid solution. The amount of acetic anhydride used is typically about 2.0-3.0 moles per equivalent of the polyamic acid. Generally, a comparable amount of tertiary amine catalyst is used.

Thermal conversion processes may or may not employ conversion chemicals (i.e., catalysts) to convert the casting solutions disclosed herein to the corresponding polyimide. If conversion chemicals are used, the process may be considered a modified-thermal conversion process. In both types of thermal conversion processes, only heat energy is used to heat the film to both dry the film of solvent and to perform the imidization reaction. Thermal conversion processes with or without conversion catalysts are generally used to prepare the polyimide films disclosed herein.

Specific method parameters are pre-selected considering that it is not just the film composition that yields the properties of interest. Rather, the cure temperature and temperature-ramp profile also play important roles in the achievement of the most desirable properties for the intended uses disclosed herein. The solutions containing the polyamic acids should be imidized at a temperature at, or higher than, the highest temperature of any subsequent processing steps (e.g. deposition of inorganic or other layer(s) necessary to produce a functioning display), but at a temperature which is lower than the temperature at which significant thermal degradation/discoloration of the polyimide occurs. It should also be noted that an inert atmosphere is generally preferred, particularly when higher processing temperatures are employed for imidization.

For the polyamic acids/polyimides disclosed herein, temperatures of 300° C. to 320° C. are typically employed when subsequent processing temperatures in excess of 300° C. are required. Choosing the proper curing temperature allows a fully cured polyimide which achieves the best balance of thermal and mechanical properties. Because of this very high temperature, an inert atmosphere is required. Typically, oxygen levels in the oven of less than 100 ppm should be employed. Very low oxygen levels enable the highest curing temperatures to be used without significant degradation/discoloration of the polymer. Catalysts that accelerate the imidization process are effective at achieving higher levels of imidization at cure temperatures between about 200° C. and 300° C. This approach may be optionally employed if the flexible device is prepared with upper cure temperatures that are below the T_{g} of the polyimide.

The amount of time in each potential cure step is also an important process consideration. Generally, the time used for the highest-temperature curing should be kept to a minimum. For 320° C. cure, for example, cure time can be up to an hour or so under an inert atmosphere; but at higher cure temperatures, this time should be shortened to avoid thermal degradation. Generally speaking, higher temperature dictates shorter time. Those skilled in the art will recognize the balance between temperature and time in order to optimize the properties of the polyimide for a particular end use.

In some embodiments, the solution containing the polyamic acid is converted into a polyimide film via a thermal conversion process.

In some embodiments of the thermal conversion process, the solution containing the polyamic acid is coated onto the matrix such that the soft-baked thickness of the resulting film is less than 50 μm.

In some embodiments of the thermal conversion process, the solution containing the polyamic acid is coated onto the matrix such that the soft-baked thickness of the resulting film is less than 40 μm.

In some embodiments of the thermal conversion process, the solution containing the polyamic acid is coated onto the matrix such that the soft-baked thickness of the resulting film is less than 30 μm.

In some embodiments of the thermal conversion process, the solution containing the polyamic acid is coated onto the matrix such that the soft-baked thickness of the resulting film is less than 20 μm.

In some embodiments of the thermal conversion process, the solution containing the polyamic acid is coated onto the matrix such that the soft-baked thickness of the resulting film is between 10 μm and 20 μm.

In some embodiments of the thermal conversion process, the solution containing the polyamic acid is coated onto the matrix such that the soft-baked thickness of the resulting film is between 15 μm and 20 μm.

In some embodiments of the thermal conversion process, the solution containing the polyamic acid is coated onto the matrix such that the soft-baked thickness of the resulting film is 18 μm.

In some embodiments of the thermal conversion process, the solution containing the polyamic acid is coated onto the matrix such that the soft-baked thickness of the resulting film is less than 10 μm.

In some embodiments of the thermal conversion process, the coated matrix is soft baked on a hot plate in proximity mode wherein nitrogen gas is used to hold the coated matrix just above the hot plate.

In some embodiments of the thermal conversion process, the coated matrix is soft baked on a hot plate in full-contact mode wherein the coated matrix is in direct contact with the hot plate surface.

In some embodiments of the thermal conversion process, the coated matrix is soft baked on a hot plate using a combination of proximity and full-contact modes.

In some embodiments of the thermal conversion process, the coated matrix is soft-baked using a hot plate set at 80° C.

In some embodiments of the thermal conversion process, the coated matrix is soft-baked using a hot plate set at 90° C.

In some embodiments of the thermal conversion process, the coated matrix is soft-baked using a hot plate set at 100° C.

In some embodiments of the thermal conversion process, the coated matrix is soft-baked using a hot plate set at 110° C.

In some embodiments of the thermal conversion process, the coated matrix is soft-baked using a hot plate set at 120° C.

In some embodiments of the thermal conversion process, the coated matrix is soft-baked using a hot plate set at 130° C.

In some embodiments of the thermal conversion process, the coated matrix is soft-baked using a hot plate set at 140° C.

In some embodiments of the thermal conversion process, the coated matrix is soft-baked for a total time of more than 10 minutes.

In some embodiments of the thermal conversion process, the coated matrix is soft-baked for a total time of less than 10 minutes.

In some embodiments of the thermal conversion process, the coated matrix is soft-baked for a total time of less than 8 minutes.

In some embodiments of the thermal conversion process, the coated matrix is soft-baked for a total time of less than 6 minutes.

In some embodiments of the thermal conversion process, the coated matrix is soft-baked for a total time of 4 minutes.

In some embodiments of the thermal conversion process, the coated matrix is soft-baked for a total time of less than 4 minutes.

In some embodiments of the thermal conversion process, the coated matrix is soft-baked for a total time of less than 2 minutes.

In some embodiments of the thermal conversion process, the soft-baked, coated matrix is subsequently cured at 2 pre-selected temperatures for 2 pre-selected time intervals, the latter of which may be the same or different.

In some embodiments of the thermal conversion process, the soft-baked, coated matrix is subsequently cured at 3 pre-selected temperatures for 3 pre-selected time intervals, each of which of the latter of which may be the same or different.

In some embodiments of the thermal conversion process, the soft-baked, coated matrix is subsequently cured at 4 pre-selected temperatures for 4 pre-selected time intervals, each of which of the latter of which may be the same or different.

In some embodiments of the thermal conversion process, the soft-baked, coated matrix is subsequently cured at 5 pre-selected temperatures for 5 pre-selected time intervals, each of which of the latter of which may be the same or different.

In some embodiments of the thermal conversion process, the soft-baked, coated matrix is subsequently cured at 6 pre-selected temperatures for 6 pre-selected time intervals, each of which of the latter of which may be the same or different.

In some embodiments of the thermal conversion process, the soft-baked, coated matrix is subsequently cured at 7 pre-selected temperatures for 7 pre-selected time intervals, each of which of the latter of which may be the same or different.

In some embodiments of the thermal conversion process the soft-baked, coated matrix is subsequently cured at 8 pre-selected temperatures for 8 pre-selected time intervals, each of which of the latter of which may be the same or different.

In some embodiments of the thermal conversion process, the soft-baked, coated matrix is subsequently cured at 9 pre-selected temperatures for 9 pre-selected time intervals, each of which of the latter of which may be the same or different.

In some embodiments of the thermal conversion process, the soft-baked, coated matrix is subsequently cured at 10 pre-selected temperatures for 10 pre-selected time intervals, each of which of the latter of which may be the same or different.

In some embodiments of the thermal conversion process, the pre-selected temperature is greater than 80° C.

In some embodiments of the thermal conversion process, the pre-selected temperature is equal to 100° C.

In some embodiments of the thermal conversion process, the pre-selected temperature is greater than 100° C.

In some embodiments of the thermal conversion process, the pre-selected temperature is equal to 150° C.

In some embodiments of the thermal conversion process, the pre-selected temperature is greater than 150° C.

In some embodiments of the thermal conversion process, the pre-selected temperature is equal to 200° C.

In some embodiments of the thermal conversion process, the pre-selected temperature is greater than 200° C.

In some embodiments of the thermal conversion process, the pre-selected temperature is equal to 250° C.

In some embodiments of the thermal conversion process, the pre-selected temperature is greater than 250° C.

In some embodiments of the thermal conversion process, the pre-selected temperature is equal to 300° C.

In some embodiments of the thermal conversion process, the pre-selected temperature is greater than 300° C.

In some embodiments of the thermal conversion process, the pre-selected temperature is equal to 350° C.

In some embodiments of the thermal conversion process, the pre-selected temperature is greater than 350° C.

In some embodiments of the thermal conversion process, the pre-selected temperature is equal to 400° C.

In some embodiments of the thermal conversion process, the pre-selected temperature is greater than 400° C.

In some embodiments of the thermal conversion process, the pre-selected temperature is equal to 450° C.

In some embodiments of the thermal conversion process, the pre-selected temperature is greater than 450° C.

In some embodiments of the thermal conversion process, one or more of the pre-selected time intervals is 2 minutes.

In some embodiments of the thermal conversion process, one or more of the pre-selected time intervals is 5 minutes.

In some embodiments of the thermal conversion process, one or more of the pre-selected time intervals is 10 minutes.

In some embodiments of the thermal conversion process, one or more of the pre-selected time intervals is 15 minutes.

In some embodiments of the thermal conversion process, one or more of the pre-selected time intervals is 20 minutes.

In some embodiments of the thermal conversion process, one or more of the pre-selected time intervals is 25 minutes.

In some embodiments of the thermal conversion process, one or more of the pre-selected time intervals is 30 minutes.

In some embodiments of the thermal conversion process, one or more of the pre-selected time intervals is 35 minutes.

In some embodiments of the thermal conversion process, one or more of the pre-selected time intervals is 40 minutes.

In some embodiments of the thermal conversion process, one or more of the pre-selected time intervals is 45 minutes.

In some of the thermal conversion process, one or more of the pre-selected time intervals is 50 minutes.

In some embodiments of the thermal conversion process, one or more of the pre-selected time intervals is 55 minutes.

In some embodiments of the thermal conversion process, one or more of the pre-selected time intervals is 60 minutes.

In some embodiments of the thermal conversion process, one or more of the pre-selected time intervals is greater than 60 minutes.

In some embodiments of the thermal conversion process, one or more of the pre-selected time intervals is between 2 minutes and 60 minutes.

In some embodiments of the thermal conversion process, one or more of the pre-selected time intervals is between 2 minutes and 90 minutes.

In some embodiments of the thermal conversion process, one or more of the pre-selected time intervals is between 2 minutes and 120 minutes.

In some embodiments of the thermal conversion process, the method for preparing a polyimide film comprises the following steps in order: coating a solution containing a polyamic acid comprising two or more tetracarboxylic acid components and one or more diamine components in a high-boiling, aprotic solvent onto a matrix; soft-baking the coated matrix; treating the soft-baked, coated matrix at a plurality of pre-selected temperatures for a plurality of pre-selected time intervals whereby the polyimide film exhibits properties that are satisfactory for use in electronics applications like those disclosed herein.

In some embodiments of the thermal conversion process, the method for preparing a polyimide film consists of the following steps in order: coating a solution containing a polyamic acid comprising two or more tetracarboxylic acid components and one or more diamine components in a high-boiling, aprotic solvent onto a matrix; soft-baking the coated matrix; treating the soft-baked, coated matrix at a plurality of pre-selected temperatures for a plurality of pre-selected time intervals whereby the polyimide film exhibits properties that are satisfactory for use in electronics applications like those disclosed herein.

In some embodiments of the thermal conversion process, the method for preparing a polyimide film consists essentially of the following steps in order: coating a solution containing a polyamic acid comprising two or more tetracarboxylic acid components and one or more diamine components in a high-boiling, aprotic solvent onto a matrix; soft-baking the coated matrix; treating the soft-baked, coated matrix at a plurality of pre-selected temperatures for a plurality of pre-selected time intervals whereby the polyimide film exhibits properties that are satisfactory for use in electronics applications like those disclosed herein.

Typically, the solutions containing polyamic acids/polyimides disclosed herein are coated/cured onto a supporting glass substrate to facilitate the processing through the rest of the display making process. At some point in the process as determined by the display maker, the polyimide coating is removed from the supporting substrate by a mechanical or laser lift off process. These processes separate the polyimide as a film with the deposited display layers from the glass and enable a flexible format. Often, this polyimide film with deposition layers is then bonded to a thicker, but still flexible, plastic film to provide support for subsequent fabrication of the display.

There are also provided modified-thermal conversion processes wherein conversion catalysts generally cause imidization reactions to run at lower temperatures than would be possible in the absence of such conversion catalysts.

In some embodiments, the solution containing the polyamic acid is converted into a polyimide film via a modified-thermal conversion process.

In some embodiments of the modified-thermal conversion process, the solution containing the polyamic acid further contains conversion catalysts.

In some embodiments of the modified-thermal conversion process, the solution containing the polyamic acid further contains conversion catalysts selected from the group consisting of tertiary amines.

In some embodiments of the modified-thermal conversion process, the solution containing the polyamic acid further contains conversion catalysts selected from the group consisting of tributylamine, dimethylethanolamine, isoquinoline, 1,2-dimethylimidazole, N-methylimidazole, 2-methylimidazole, 2-ethyl-4-imidazole, 3,5-dimethylpyridine, 3,4-dimethylpyridine, 2,5-dimethylpyridine, 5-methylbenzimidazole, and the like.

In some embodiments of the modified-thermal conversion process, the conversion catalyst is present at 5 weight percent or less of the solution containing the polyamic acid.

In some embodiments of the modified-thermal conversion process, the conversion catalyst is present at 3 weight percent or less of the solution containing the polyamic acid.

In some embodiments of the modified-thermal conversion process, the conversion catalyst is present at 1 weight percent or less of the solution containing the polyamic acid.

In some embodiments of the modified-thermal conversion process, the conversion catalyst is present at 1 weight percent of the solution containing the polyamic acid.

In some embodiments of the modified-thermal conversion process, the solution containing the polyamic acid further contains tributylamine as a conversion catalyst.

In some embodiments of the modified-thermal conversion process, the solution containing the polyamic acid further contains dimethylethanolamine as a conversion catalyst.

In some embodiments of the modified-thermal conversion process, the solution containing the polyamic acid further contains isoquinoline as a conversion catalyst.

In some embodiments of the modified-thermal conversion process, the solution containing the polyamic acid further contains 1,2-dimethylimidazole as a conversion catalyst.

In some embodiments of the modified-thermal conversion process, the solution containing the polyamic acid further contains 3,5-dimethylpyridine as a conversion catalyst.

In some embodiments of the modified-thermal conversion process, the solution containing the polyamic acid further contains 5-methylbenzimidazole as a conversion catalyst.

In some embodiments of the modified-thermal conversion process, the solution containing the polyamic acid further contains N-methylimidazole as a conversion catalyst.

In some embodiments of the modified-thermal conversion process, the solution containing the polyamic acid further contains 2-methylimidazole as a conversion catalyst.

In some embodiments of the modified-thermal conversion process, the solution containing the polyamic acid further contains 2-ethyl-4-imidazole as a conversion catalyst.

In some embodiments of the modified-thermal conversion process, the solution containing the polyamic acid further contains 3,4-dimethylpyridine as a conversion catalyst.

In some embodiments of the modified-thermal conversion process, the solution containing the polyamic acid further contains 2,5-dimethylpyridine as a conversion catalyst.

In some embodiments of the modified-thermal conversion process, the solution containing the polyamic acid is coated onto the matrix such that the soft-baked thickness of the resulting film is less than 50 μm.

In some embodiments of the modified-thermal conversion process, the solution containing the polyamic acid is coated onto the matrix such that the soft-baked thickness of the resulting film is less than 40 μm.

In some embodiments of the modified-thermal conversion process, the solution containing the polyamic acid is coated onto the matrix such that the soft-baked thickness of the resulting film is less than 30 μm.

In some embodiments of the modified-thermal conversion process, the solution containing the polyamic acid is coated onto the matrix such that the soft-baked thickness of the resulting film is less than 20 μm.

In some embodiments of the modified-thermal conversion process, the solution containing the polyamic acid is coated onto the matrix such that the soft-baked thickness of the resulting film is between 10 μm and 20 μm.

In some embodiments of the modified-thermal conversion process, the solution containing the polyamic acid is coated onto the matrix such that the soft-baked thickness of the resulting film is between 15 μm and 20 μm.

In some embodiments of the modified-thermal conversion process, the solution containing the polyamic acid is coated onto the matrix such that the soft-baked thickness of the resulting film is 18 μm.

In some embodiments of the modified-thermal conversion process, the solution containing the polyamic acid is coated onto the matrix such that the soft-baked thickness of the resulting film is less than 10 μm.

In some embodiments of the modified-thermal conversion process, the coated matrix is soft baked on a hot plate in proximity mode wherein nitrogen gas is used to hold the coated matrix just above the hot plate.

In some embodiments of the modified-thermal conversion process, the coated matrix is soft baked on a hot plate in full-contact mode wherein the coated matrix is in direct contact with the hot plate surface.

In some embodiments of the modified-thermal conversion process, the coated matrix is soft baked on a hot plate using a combination of proximity and full-contact modes.

In some embodiments of the modified-thermal conversion process, the coated matrix is soft-baked using a hot plate set at 80° C.

In some embodiments of the modified-thermal conversion process, the coated matrix is soft-baked using a hot plate set at 90° C.

In some embodiments of the modified-thermal conversion process, the coated matrix is soft-baked using a hot plate set at 100° C.

In some embodiments of the modified-thermal conversion process, the coated matrix is soft-baked using a hot plate set at 110° C.

In some embodiments of the modified-thermal conversion process, the coated matrix is soft-baked using a hot plate set at 120° C.

In some embodiments of the modified-thermal conversion process, the coated matrix is soft-baked using a hot plate set at 130° C.

In some embodiments of the modified-thermal conversion process, the coated matrix is soft-baked using a hot plate set at 140° C.

In some embodiments of the modified-thermal conversion process, the coated matrix is soft-baked for a total time of more than 10 minutes.

In some embodiments of the modified-thermal conversion process, the coated matrix is soft-baked for a total time of less than 10 minutes.

In some embodiments of the modified-thermal conversion process, the coated matrix is soft-baked for a total time of less than 8 minutes.

In some embodiments of the modified-thermal conversion process, the coated matrix is soft-baked for a total time of less than 6 minutes.

In some embodiments of the modified-thermal conversion process, the coated matrix is soft-baked for a total time of 4 minutes.

In some embodiments of the modified-thermal conversion process, the coated matrix is soft-baked for a total time of less than 4 minutes.

In some embodiments of the modified-thermal conversion process, the coated matrix is soft-baked for a total time of less than 2 minutes.

In some embodiments of the modified-thermal conversion process, the soft-baked, coated matrix is subsequently cured at 2 pre-selected temperatures for 2 pre-selected time intervals, the latter of which may be the same or different.

In some embodiments of the modified-thermal conversion process, the soft-baked, coated matrix is subsequently cured at 3 pre-selected temperatures for 3 pre-selected time intervals, each of which of the latter of which may be the same or different.

In some embodiments of the modified-thermal conversion process, the soft-baked, coated matrix is subsequently cured at 4 pre-selected temperatures for 4 pre-selected time intervals, each of which of the latter of which may be the same or different.

In some embodiments of the modified-thermal conversion process, the soft-baked, coated matrix is subsequently cured at 5 pre-selected temperatures for 5 pre-selected time intervals, each of which of the latter of which may be the same or different.

In some embodiments of the modified-thermal conversion process, the soft-baked, coated matrix is subsequently cured at 6 pre-selected temperatures for 6 pre-selected time intervals, each of which of the latter of which may be the same or different.

In some embodiments of the modified-thermal conversion process, the soft-baked, coated matrix is subsequently cured at 7 pre-selected temperatures for 7 pre-selected time intervals, each of which of the latter of which may be the same or different.

In some embodiments of the modified-thermal conversion process the soft-baked, coated matrix is subsequently cured at 8 pre-selected temperatures for 8 pre-selected time intervals, each of which of the latter of which may be the same or different.

In some embodiments of the modified-thermal conversion process, the soft-baked, coated matrix is subsequently cured at 9 pre-selected temperatures for 9 pre-selected time intervals, each of which of the latter of which may be the same or different.

In some embodiments of the modified-thermal conversion process, the soft-baked, coated matrix is subsequently cured at 10 pre-selected temperatures for 10 pre-selected time intervals, each of which of the latter of which may be the same or different.

In some embodiments of the modified-thermal conversion process, the pre-selected temperature is greater than 80° C.

In some embodiments of the modified-thermal conversion process, the pre-selected temperature is equal to 100° C.

In some embodiments of the modified-thermal conversion process, the pre-selected temperature is greater than 100° C.

In some embodiments of the modified-thermal conversion process, the pre-selected temperature is equal to 150° C.

In some embodiments of the modified-thermal conversion process, the pre-selected temperature is greater than 150° C.

In some embodiments of the modified-thermal conversion process, the pre-selected temperature is equal to 200° C.

In some embodiments of the modified-thermal conversion process, the pre-selected temperature is greater than 200° C.

In some embodiments of the modified-thermal conversion process, the pre-selected temperature is equal to 220° C.

In some embodiments of the modified-thermal conversion process, the pre-selected temperature is greater than 220° C.

In some embodiments of the modified-thermal conversion process, the pre-selected temperature is equal to 230° C.

In some embodiments of the modified-thermal conversion process, the pre-selected temperature is greater than 230° C.

In some embodiments of the modified-thermal conversion process, the pre-selected temperature is equal to 240° C.

In some embodiments of the modified-thermal conversion process, the pre-selected temperature is greater than 240° C.

In some embodiments of the modified-thermal conversion process, the pre-selected temperature is equal to 250° C.

In some embodiments of the modified-thermal conversion process, the pre-selected temperature is greater than 250° C.

In some embodiments of the modified-thermal conversion process, the pre-selected temperature is equal to 260° C.

In some embodiments of the modified-thermal conversion process, the pre-selected temperature is greater than 260° C.

In some embodiments of the modified-thermal conversion process, the pre-selected temperature is equal to 270° C.

In some embodiments of the modified-thermal conversion process, the pre-selected temperature is greater than 270° C.

In some embodiments of the modified-thermal conversion process, the pre-selected temperature is equal to 280° C.

In some embodiments of the modified-thermal conversion process, the pre-selected temperature is greater than 280° C.

In some embodiments of the modified-thermal conversion process, the pre-selected temperature is equal to 290° C.

In some embodiments of the modified-thermal conversion process, the pre-selected temperature is greater than 290° C.

In some embodiments of the modified-thermal conversion process, the pre-selected temperature is equal to 300° C.

In some embodiments of the modified-thermal conversion process, the pre-selected temperature is less than 300° C.

In some embodiments of the modified-thermal conversion process, the pre-selected temperature is less than 290° C.

In some embodiments of the modified-thermal conversion process, the pre-selected temperature is less than 280° C.

In some embodiments of the modified-thermal conversion process, the pre-selected temperature is less than 270° C.

In some embodiments of the modified-thermal conversion process, the pre-selected temperature is less than 260° C.

In some embodiments of the modified-thermal conversion process, the pre-selected temperature is less than 250° C.

In some embodiments of the modified-thermal conversion process, one or more of the pre-selected time intervals is 2 minutes.

In some embodiments of the modified-thermal conversion process, one or more of the pre-selected time intervals is 5 minutes.

In some embodiments of the modified-thermal conversion process, one or more of the pre-selected time intervals is 10 minutes.

In some embodiments of the modified-conversion process, one or more of the pre-selected time intervals is 15 minutes.

In some embodiments of the modified-thermal conversion process, one or more of the pre-selected time intervals is 20 minutes.

In some embodiments of the modified-thermal conversion process, one or more of the pre-selected time intervals is 25 minutes.

In some embodiments of the modified-thermal conversion process, one or more of the pre-selected time intervals is 30 minutes.

In some embodiments of the modified-thermal conversion process, one or more of the pre-selected time intervals is 35 minutes.

In some embodiments of the modified-thermal conversion process, one or more of the pre-selected time intervals is 40 minutes.

In some embodiments of the modified-thermal conversion process, one or more of the pre-selected time intervals is 45 minutes.

In some embodiments of the modified-thermal conversion process, one or more of the pre-selected time intervals is 50 minutes.

In some embodiments of the modified-thermal conversion process, one or more of the pre-selected time intervals is 55 minutes.

In some embodiments of the modified-thermal conversion process, one or more of the pre-selected time intervals is 60 minutes.

In some embodiments of the modified-thermal conversion process, one or more of the pre-selected time intervals is greater than 60 minutes.

In some embodiments of the modified-thermal conversion process, one or more of the pre-selected time intervals is between 2 minutes and 60 minutes.

In some embodiments of the modified-thermal conversion process, one or more of the pre-selected time intervals is between 2 minutes and 90 minutes.

In some embodiments of the modified-thermal conversion process, one or more of the pre-selected time intervals is between 2 minutes and 120 minutes.

In some embodiments of the modified-thermal conversion process, the method for preparing a polyimide film comprises the following steps in order: coating a solution containing a polyamic acid comprising two or more tetracarboxylic acid components and one or more diamine components and a conversion chemical in a high-boiling, aprotic solvent onto a matrix; soft-baking the coated matrix; treating the soft-baked, coated matrix at a plurality of pre-selected temperatures for a plurality of pre-selected time intervals whereby the polyimide film exhibits properties that are satisfactory for use in electronics applications like those disclosed herein.

In some embodiments of the modified-thermal conversion process, the method for preparing a polyimide film consists of the following steps in order: coating a solution containing a polyamic acid comprising two or more tetracarboxylic acid components and one or more diamine components and a conversion chemical in a high-boiling, aprotic solvent onto a matrix; soft-baking the coated matrix; treating the soft-baked, coated matrix at a plurality of pre-selected temperatures for a plurality of pre-selected time intervals whereby the polyimide film exhibits properties that are satisfactory for use in electronics applications like those disclosed herein.

In some embodiments of the modified-thermal conversion process, the method for preparing a polyimide film consists essentially of the following steps in order: coating a solution containing a polyamic acid comprising two or more tetracarboxylic acid components and one or more diamine components and a conversion chemical in a high-boiling, aprotic solvent onto a matrix; soft-baking the coated matrix; treating the soft-baked, coated matrix at a plurality of pre-selected temperatures for a plurality of pre-selected time intervals whereby the polyimide film exhibits properties that are satisfactory for use in electronics applications like those disclosed herein.

### 5. Flexible Replacement for Glass in an Electronic Device

The polyimide films disclosed herein can be suitable for use in a number of layers in electronic display devices such as OLED and LCD Displays. Nonlimiting examples of such layers include device substrates, touch panels, color filters, and cover films. The particular materials' properties requirements for each application are unique and may be addressed by appropriate composition(s) and processing condition(s) for the polyimide films disclosed herein.

In some embodiments, the flexible replacement for glass in an electronic device is a polyimide film having the repeat unit of Formula I

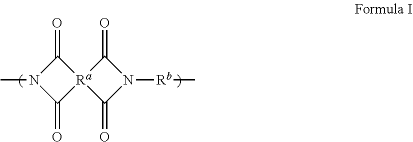

wherein:
R^{a} is a quadrivalent organic group derived from two or more acid dianhydrides wherein at least one of the acid dianhydrides is an aliphatic dianhydride and R^{b} is a divalent organic group derived from one or more diamines;
   such that:
the in-plane coefficient of thermal expansion (CTE) is less than 40 ppm/° C. between 50° C. and 250° C.;
the glass transition temperature (T_{g}) is greater than 300° C. for a polyimide film cured at a temperature above 300° C.;
the 1% TGA weight loss temperature is greater than 350° C.; the tensile modulus is greater than 5 GPa;
the elongation to break is greater than 5%;
the tensile strength is greater than 100 MPa;
the transmittance at 308 nm is approximately 0%;
the transmittance at 355 nm is less than 1%;
the transmittance at 360 nm is greater than 5%;
the transmittance at 370 nm is greater than 10%;
the transmittance at 400 nm is greater than 40%;
the transmittance at 430 nm is greater than 80%;
the transmittance at 450 nm is greater than 85%;
the transmittance at 550 nm is greater than or equal to 88%;
the optical retardation at 633 nm is less than 300 nm for a 10 micron film;
the birefringence at 633 nm is less than 0.0300; and
b* is less than 3.0.

In some embodiments, the flexible replacement for glass in an electronic device is a polyimide film having the repeat unit of Formula I and the composition disclosed herein.

### 6. The Electronic Device

Organic electronic devices that may benefit from having one or more layers including at least one compound as described herein include, but are not limited to, (1) devices that convert electrical energy into radiation (e.g., a light-emitting diode, light emitting diode display, lighting device, luminaire, or diode laser), (2) devices that detect signals through electronics processes (e.g., photodetectors, photoconductive cells, photoresistors, photoswitches, phototransistors, phototubes, IR detectors, biosensors), (3) devices that convert radiation into electrical energy, (e.g., a photovoltaic device or solar cell), (4) devices that convert light of one wavelength to light of a longer wavelength, (e.g., a down-converting phosphor device); and (5) devices that include one or more electronic components that include one or more organic semi-conductor layers (e.g., a transistor or diode). Other uses for the compositions according to the present invention include coating materials for memory storage devices, antistatic films, biosensors, electrochromic devices, solid electrolyte capacitors, energy storage devices such as a rechargeable battery, and electromagnetic shielding applications.

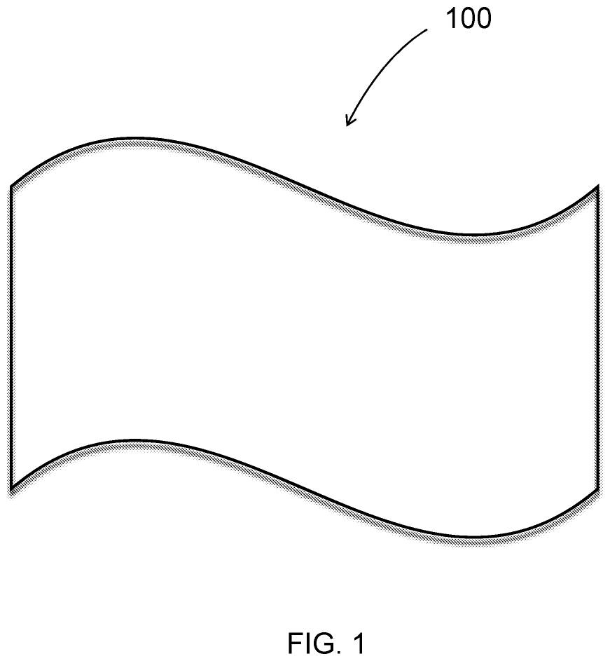

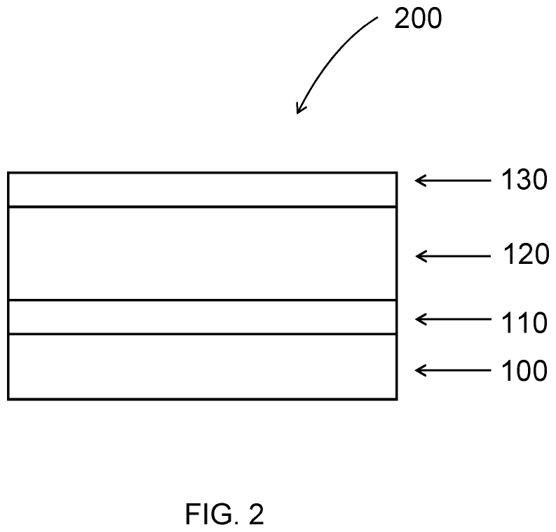

One illustration of a polyimide film that can act as a flexible replacement for glass as described herein is shown in FIG. 1. The flexible film 100 can have the properties as described in the embodiments of this disclosure. In some embodiments, the polyimide film that can act as a flexible replacement for glass is included in an electronic device. FIG. 2 illustrates the case when the electronic device 200 is an organic electronic device. The device 200 has a substrate 100, an anode layer 110 and a second electrical contact layer, a cathode layer 130, and a photoactive layer 120 between them. Additional layers may optionally be present. Adjacent to the anode may be a hole injection layer (not shown), sometimes referred to as a buffer layer. Adjacent to the hole injection layer may be a hole transport layer (not shown), including hole transport material. Adjacent to the cathode may be an electron transport layer (not shown), including an electron transport material. As an option, devices may use one or more additional hole injection or hole transport layers (not shown) next to the anode 110 and/or one or more additional electron injection or electron transport layers (not shown) next to the cathode 130. Layers between 110 and 130 are individually and collectively referred to as the organic active layers. Additional layers that may or may not be present include color filters, touch panels, and/or cover sheets. One or more of these layers, in addition to the substrate 100, may also be made from the polyimide films disclosed herein.

The different layers will be discussed further herein with reference to FIG. 2. However, the discussion applies to other configurations as well.

In some embodiments, the different layers have the following range of thicknesses: substrate 100, 5-100 microns, anode 110, 500-5000 Å, in some embodiments, 1000-2000 Å; hole injection layer (not shown), 50-2000 Å, in some embodiments, 200-1000 Å; hole transport layer (not shown), 50-3000 Å, in some embodiments, 200-2000 Å; photoactive layer 120, 10-2000 Å, in some embodiments, 100-1000 Å; electron transport layer (not shown), 50-2000 Å, in some embodiments, 100-1000 Å; cathode 130, 200-10000 Å, in some embodiments, 300-5000 Å. The desired ratio of layer thicknesses will depend on the exact nature of the materials used.

In some embodiments, the organic electronic device (OLED) contains a flexible replacement for glass as disclosed herein.

In some embodiments, an organic electronic device includes a substrate, an anode, a cathode, and a photoactive layer therebetween, and further includes one or more additional organic active layers. In some embodiments, the additional organic active layer is a hole transport layer. In some embodiments, the additional organic active layer is an electron transport layer. In some embodiments, the additional organic layers are both hole transport and electron transport layers.

The anode 110 is an electrode that is particularly efficient for injecting positive charge carriers. It can be made of, for example materials containing a metal, mixed metal, alloy, metal oxide or mixed-metal oxide, or it can be a conducting polymer, and mixtures thereof. Suitable metals include the Group 11 metals, the metals in Groups 4, 5, and 6, and the Group 8-10 transition metals. If the anode is to be light-transmitting, mixed-metal oxides of Groups 12, 13 and 14 metals, such as indium-tin-oxide, are generally used. The anode may also include an organic material such as polyaniline as described in “Flexible light-emitting diodes made from soluble conducting polymer,” Nature vol. 357, pp 477 479 (11 Jun. 1992). At least one of the anode and cathode should be at least partially transparent to allow the generated light to be observed.

Optional hole injection layers can include hole injection materials. The term “hole injection layer” or “hole injection material” is intended to mean electrically conductive or semiconductive materials and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. Hole injection materials may be polymers, oligomers, or small molecules, and may be in the form of solutions, dispersions, suspensions, emulsions, colloidal mixtures, or other compositions.

The hole injection layer can be formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like. The hole injection layer 120 can include charge transfer compounds, and the like, such as copper phthalocyanine and the tetrathiafulvalene-tetracyanoquinodimethane system (TTF-TCNQ). In some embodiments, the hole injection layer 120 is made from a dispersion of a conducting polymer and a colloid-forming polymeric acid. Such materials have been described in, for example, published U.S. patent applications 2004-0102577, 2004-0127637, and 2005-0205860.

Other layers can include hole transport materials. Examples of hole transport materials for the hole transport layer have been summarized for example, in Kirk-Othmer Encyclopedia of Chemical Technology, Fourth Edition, Vol. 18, p. 837-860, 1996, by Y. Wang. Both hole transporting small molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 4,4′-bis(carbazol-9-yl)biphenyl (CBP); 1,3-bis(carbazol-9-yl)benzene (mCP); 1,1-bis[(di-4-tolylamino) phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3[p-(diethylamino)styryl]-5-[p-(diethylamino)phenyl] pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate. In some cases, triarylamine polymers are used, especially triarylamine-fluorene copolymers. In some cases, the polymers and copolymers are crosslinkable. Examples of crosslinkable hole transport polymers can be found in, for example, published US patent application 2005-0184287 and published PCT application WO 2005/052027. In some embodiments, the hole transport layer is doped with a p-dopant, such as tetrafluorotetracyanoquinodimethane and perylene-3,4,9,10-tetracarboxylic-3,4,9,10-dianhydride.

Depending upon the application of the device, the photoactive layer 120 can be a light-emitting layer that is activated by an applied voltage (such as in a light-emitting diode or light-emitting electrochemical cell), a layer of material that absorbs light and emits light having a longer wavelength (such as in a down-converting phosphor device), or a layer of material that responds to radiant energy and generates a signal with or without an applied bias voltage (such as in a photodetector or photovoltaic device).

In some embodiments, the photoactive layer includes a compound comprising an emissive compound having as a photoactive material. In some embodiments, the photoactive layer further comprises a host material. Examples of host materials include, but are not limited to, chrysenes, phenanthrenes, triphenylenes, phenanthrolines, naphthalenes, anthracenes, quinolines, isoquinolines, quinoxalines, phenylpyridines, carbazoles, indolocarbazoles, furans, benzofurans, dibenzofurans, benzodifurans, and metal quinolinate complexes. In some embodiments, the host materials are deuterated.

In some embodiments, the photoactive layer comprises (a) a dopant capable of electroluminescence having an emission maximum between 380 and 750 nm, (b) a first host compound, and (c) a second host compound. Suitable second host compounds are described above.

In some embodiments, the photoactive layer includes only (a) a dopant capable of electroluminescence having an emission maximum between 380 and 750 nm, (b) a first host compound, and (c) a second host compound, where additional materials that would materially alter the principle of operation or the distinguishing characteristics of the layer are not present.

In some embodiments, the first host is present in higher concentration than the second host, based on weight in the photoactive layer.

In some embodiments, the weight ratio of first host to second host in the photoactive layer is in the range of 10:1 to 1:10. In some embodiments, the weight ratio is in the range of 6:1 to 1:6; in some embodiments, 5:1 to 1:2; in some embodiments, 3:1 to 1:1.

In some embodiments, the weight ratio of dopant to the total host is in the range of 1:99 to 20:80; in some embodiments, 5:95 to 15:85.

In some embodiments, the photoactive layer comprises (a) a red light-emitting dopant, (b) a first host compound, and (c) a second host compound.

In some embodiments, the photoactive layer comprises (a) a green light-emitting dopant, (b) a first host compound, and (c) a second host compound.

In some embodiments, the photoactive layer comprises (a) a yellow light-emitting dopant, (b) a first host compound, and (c) a second host compound.

Optional layers can function both to facilitate electron transport, and also serve as a confinement layer to prevent quenching of the exciton at layer interfaces. Preferably, this layer promotes electron mobility and reduces exciton quenching.

In some embodiments, such layers include other electron transport materials. Examples of electron transport materials which can be used in the optional electron transport layer, include metal chelated oxinoid compounds, including metal quinolate derivatives such as tris(8-hydroxyquinolato)aluminum (AIQ), bis(2-methyl-8-quinolinolato)(p-phenylphenolato) aluminum (BAlq), tetrakis-(8-hydroxyquinolato)hafnium (HfQ) and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); triazines; fullerenes; and mixtures thereof. In some embodiments, the electron transport material is selected from the group consisting of metal quinolates and phenanthroline derivatives. In some embodiments, the electron transport layer further includes an n-dopant. N-dopant materials are well known. The n-dopants include, but are not limited to, Group 1 and 2 metals; Group 1 and 2 metal salts, such as LiF, CsF, and Cs₂CO₃; Group 1 and 2 metal organic compounds, such as Li quinolate; and molecular n-dopants, such as leuco dyes, metal complexes, such as W₂(hpp)₄ where hpp=1,3,4,6,7,8-hexahydro-2H-pyrimido-[1,2-a]-pyrimidine and cobaltocene, tetrathianaphthacene, bis(ethylenedithio)tetrathiafulvalene, heterocyclic radicals or diradicals, and the dimers, oligomers, polymers, dispiro compounds and polycycles of heterocyclic radical or diradicals.

An optional electron injection layer may be deposited over the electron transport layer. Examples of electron injection materials include, but are not limited to, Li-containing organometallic compounds, LiF, Li₂O, Li quinolate, Cs-containing organometallic compounds, CsF, Cs₂O, and Cs₂CO₃. This layer may react with the underlying electron transport layer, the overlying cathode, or both. When an electron injection layer is present, the amount of material deposited is generally in the range of 1-100 Å, in some embodiments 1-10 Å.

The cathode 130 is an electrode that is particularly efficient for injecting electrons or negative charge carriers. The cathode can be any metal or nonmetal having a lower work function than the anode. Materials for the cathode can be selected from alkali metals of Group 1 (e.g., Li, Cs), the Group 2 (alkaline earth) metals, the Group 12 metals, including the rare earth elements and lanthanides, and the actinides. Materials such as aluminum, indium, calcium, barium, samarium and magnesium, as well as combinations, can be used.

It is known to have other layers in organic electronic devices. For example, there can be layers (not shown) between the anode 110 and hole injection layer (not shown) to control the amount of positive charge injected and/or to provide band-gap matching of the layers, or to function as a protective layer. Layers that are known in the art can be used, such as copper phthalocyanine, silicon oxy-nitride, fluorocarbons, silanes, or an ultra-thin layer of a metal, such as Pt. Alternatively, some or all of anode layer 110, active layer 120, or cathode layer 130, can be surface-treated to increase charge carrier transport efficiency. The choice of materials for each of the component layers is preferably determined by balancing the positive and negative charges in the emitter layer to provide a device with high electroluminescence efficiency.

It is understood that each functional layer can be made up of more than one layer.

The device layers can generally be formed by any deposition technique, or combinations of techniques, including vapor deposition, liquid deposition, and thermal transfer. Substrates such as glass, plastics, and metals can be used. Conventional vapor deposition techniques can be used, such as thermal evaporation, chemical vapor deposition, and the like. The organic layers can be applied from solutions or dispersions in suitable solvents, using conventional coating or printing techniques, including but not limited to spin-coating, dip-coating, roll-to-roll techniques, ink-jet printing, continuous nozzle printing, screen-printing, gravure printing and the like.

For liquid deposition methods, a suitable solvent for a particular compound or related class of compounds can be readily determined by one skilled in the art. For some applications, it is desirable that the compounds be dissolved in non-aqueous solvents. Such non-aqueous solvents can be relatively polar, such as C₁ to C₂₀ alcohols, ethers, and acid esters, or can be relatively non-polar such as C₁ to C₁₂ alkanes or aromatics such as toluene, xylenes, trifluorotoluene and the like. Other suitable liquids for use in making the liquid composition, either as a solution or dispersion as described herein, including the new compounds, includes, but not limited to, chlorinated hydrocarbons (such as methylene chloride, chloroform, chlorobenzene), aromatic hydrocarbons (such as substituted and non-substituted toluenes and xylenes), including triflurotoluene), polar solvents (such as tetrahydrofuran (THP), N-methyl pyrrolidone) esters (such as ethylacetate) alcohols (isopropanol), ketones (cyclopentatone) and mixtures thereof. Suitable solvents for electroluminescent materials have been described in, for example, published PCT application WO 2007/145979.

In some embodiments, the device is fabricated by liquid deposition of the hole injection layer, the hole transport layer, and the photoactive layer, and by vapor deposition of the anode, the electron transport layer, an electron injection layer and the cathode onto the flexible substrate.

It is understood that the efficiency of devices can be improved by optimizing the other layers in the device. For example, more efficient cathodes such as Ca, Ba or LiF can be used. Shaped substrates and novel hole transport materials that result in a reduction in operating voltage or increase quantum efficiency are also applicable. Additional layers can also be added to tailor the energy levels of the various layers and facilitate electroluminescence.

In some embodiments, the device has the following structure, in order: substrate, anode, hole injection layer, hole transport layer, photoactive layer, electron transport layer, electron injection layer, cathode.

Although methods and materials similar or equivalent to those described herein can be used in the practice or testing of the present invention, suitable methods and materials are described below. In addition, the materials, methods, and examples are illustrative only and not intended to be limiting. All publications, patent applications, patents, and other references mentioned herein are incorporated by reference in their entirety.

### EXAMPLES

The concepts described herein will be further illustrated in the following examples, which do not limit the scope of the invention described in the claims.

### Example A—Preparation of Polyamic Acid Copolymer of BPDA/6FDA/CBDA//TFMB 10/20/70//100 in NMP

Into a 2-liter reaction flask equipped with a nitrogen inlet and outlet, mechanical stirrer, and thermocouple were charged 67.20 g of trifluoromethyl benzidene (TFMB) and 400 g of 1-methyl-2-pyrrolidinone (NMP). The mixture was agitated under nitrogen at room temperature for about 30 minutes to dissolve the TFMB. Afterwards, 6.17 g of 3,3′4,4′-biphenyl tetracarboxylic dianhydride (BPDA) was added slowly in portions to the stirring solution of the diamine followed by 18.64 g 6FDA (hexafluoroisopropylidene dianhydride) in portions. After this, 27.98 g cyclobutane disnhydride (CBDA) was added to the reaction with stirring. The addition rate of the dianhydrides was controlled, to maintain the maximum reaction temperature <40° C. After completion of the dianhydride addition, and additional 280 g of NMP was used to wash in any remaining dianhydride powder from containers and the walls of the reaction flask. The dianhydrides dissolved and reacted and the polyamic acid (PAA) solution was stirred for ˜24 hr. After this, CBDA was added in 0.20 g increments to raise the molecular weight of the polymer and viscosity of the polymer solution in a controlled manner. Brookfield cone and plate viscometry was used to monitor the solution viscosity by removing small samples from the reaction flask for testing. A total of 0.60 g of CBDA was added.

The reaction proceeded for an additional 48 hours at room temperature under gentle agitation to allow for polymer equilibration. Final viscosity of the polymer solution was 9767 cps at 25° C. The contents of the flask were poured into a 2-liter HDPE bottle, tightly capped, and stored in a refrigerator for later use.

### Example 1—Spin Coating and Imidization of Polyamic Acid Solution to BPDA/6FDA/CBDA//TFMB 10/20/70//100 Polyimide Coating

A portion of the solution prepared Example 1 was pressure filtered through a Whatman PolyCap HD 0.45 μm absolute filter into a EFD Nordsen dispensing syringe barrel. This syringe barrel was attached to an EFD Nordsen dispensing unit to apply several ml of polymer solution onto, and spin coat, a 6″ silicon wafer. The spin speed was varied into order to obtain the desired soft-baked thickness of about 18 μm. Soft-baking was accomplished after coating by placing the coated wafer onto a hot plate set at 110° C., first in proximity mode (nitrogen flow to hold wafer just off the surface of the hot plate) for 1 minute, followed by direct contact with the hot plate surface for 3 minutes. The thickness of the soft-baked film was measured on a Tencor profilometer by removing sections of the coating from the wafer and then measuring the difference between coated and uncoated areas of the wafer. The spin coating conditions were varied as necessary to obtain the desired ˜15 μm uniform coating across the wafer surface.

Once the spin coating conditions were determined, several wafers were coated, soft-baked, and placed in a Tempress tube furnace. After closing the furnace, a nitrogen purge was applied and the furnace was ramped to 100° C. at 2.5° C./min and held there for about 30 min to allow a thorough purge with nitrogen, then the temperature was ramped at 2° C./min to 200° C. and held there for 30 min. Next, the temperature was ramped to 320° C. at 4° C./min and held there for 60 min. After this, the heating was stopped and the temperature allowed to return slowly to ambient temperature (no external cooling). Afterward, the wafers were removed from the furnace and the coatings were removed from the wafers by scoring the coating around the edge of the wafer with a knife and then soaking the wafers in water for at least several hours to lift the coating off the wafer. The resulting polyimide films allowed to dry and then subject to various property measurements. For example, a Hunter Lab spectrophotometer was used to measure b* and yellow index along with % transmittance (% T) over the wavelength range 350 nm-780 nm. Thermal measurements on films were made using a combination of thermogravimetric analysis and thermomechanical analysis as appropriate for the specific parameters reported herein. Mechanical properties were measured using equipment from Instron. Property measurements for this film are presented in Table 3.

### Example B—Preparation of Polyamic Acid Copolymer of PMDA/BPDA/CBDA/6FDA//TFMB 10/30/40/20//100 in NMP

This solution containing polyamic acid PMDA/BPDA/CBDA/6FDA//TFMB 10/30/40/20//100 was prepared in NMP in an analogous manner to that done in Example A above, except that specific dianhydrides and diamines, and their respective relative amounts, were appropriate for this target composition. The prepared solution was poured into a 2-liter HDPE bottle, tightly capped, and stored in a refrigerator for later use.

### Example 2—Spin Coating and Imidization of Polyamic Acid Solution to PMDA/BPDA/CBDA/6FDA//TFMB 10/30/40/20//100 Polyimide Coating

In a manner analogous to that described above in Example 1, the solution containing the polyamic acid copolymer prepared in Example B was filtered, coated onto a 6″ silicon wafer, soft-baked, and imidized. Maximum cure temperature of the imidization temperature profile was 320° C. The heating was then stopped and the temperature allowed to return slowly to ambient temperature (no external cooling). Afterward, the wafers were removed from the furnace and the coatings were removed from the wafers by scoring the coating around the edge of the wafer with a knife and then soaking the wafers in water for at least several hours to lift the coating off the wafer. The resulting polyimide films allowed to dry and then subject to various property measurements. For example, a Hunter Lab spectrophotometer was used to measure b* and yellow index along with % transmittance (% T) over the wavelength range 350 nm-780 nm. Thermal measurements on films were made using a combination of thermogravimetric analysis and thermomechanical analysis as appropriate for the specific parameters reported herein. Mechanical properties were measured using equipment from Instron. Property measurements for this film are presented in Table 3.

### Comparative Example A—Preparation of Polyamic Acid Copolymer of BPDA/PMDA/6FDA//TFMB 70/10/20//100 in NMP

This solution containing polyamic acid BPDA/PMDA/6FDA//TFMB 70/10/20//100 was prepared in NMP in an analogous manner to that done in Examples A and B above, except that specific dianhydrides and diamines, and their respective relative amounts, were appropriate for this target composition. The prepared solution was poured into a 2-liter HDPE bottle, tightly capped, and stored in a refrigerator for later use.

### Comparative Example 1—Spin Coating and Imidization of Polyamic Acid Solution to BPDA/PMDA/6FDA//TFMB 70/10/20//100 Polyimide Coating

In a manner analogous to that described above in Examples 1 and 2, the solution containing the polyamic acid copolymer prepared in Comparative Example A was filtered, coated onto a 6″ silicon wafer, soft-baked, and imidized. Maximum cure temperature of the imidization temperature profile was 375° C. The heating was then stopped and the temperature allowed to return slowly to ambient temperature (no external cooling). Afterward, the wafers were removed from the furnace and the coatings were removed from the wafers by scoring the coating around the edge of the wafer with a knife and then soaking the wafers in water for at least several hours to lift the coating off the wafer. The resulting polyimide films allowed to dry and then subject to various property measurements. For example, a Hunter Lab spectrophotometer was used to measure b* and yellow index along with % transmittance (% T) over the wavelength range 350 nm-780 nm. Thermal measurements on films were made using a combination of thermogravimetric analysis and thermomechanical analysis as appropriate for the specific parameters reported herein. Mechanical properties were measured using equipment from Instron. Property measurements for this film are presented in Table 3.

TABLE 3
Compositions/Properties of Polyimide Films

| | | Example 1 | Example 2 | Comparative Example 1 |
|---|---|---|---|---|
| Film | Composition | BPDA/6FDA/CBDA//TFMB | PMDA/BPDA/CBDA/6FDA//TFMB | BPDA/PMDA/6FDA//TFMB |
| Properties | (mole %) | 10/20/70//100 | 10/30/40/20//100 | 70/10/20//100 |
| | Cure Temp (° C.) | 320 | 320 | 375 |
| | Film Thickness | 9.69 | 10.17 | 10.12 |
| | (μm) | | | |
| Thermal | T_{g} (° C.) | 381 | 359 | 362 |
| Properties | CTE | 36.18 | 38.28 | 42.5 |
| | (ppm/° C.) | | | |
| | 1.0% TGA WT | 387.66 | 396.3 | 500.81 |
| | LOSS (° C.) | | | |
| Mechanical | Tensile | 5.09 | 4.95 | 4.38 |
| Properties | Modulus (GPa) | | | |
| | Tensile | 138.29 | 170.43 | 187.03 |
| | Strength (MPa) | | | |
| | Elongation to | 10.73 | 11.74 | 30.51 |
| | Break (%) | | | |
| Optical | 360 nm | 18.05 | 3.97 | 1.85 |
| Properties | 370 nm | 37.02 | 13.56 | 5.89 |
| Transmittance | 400 nm | 77.36 | 70.23 | 66.55 |
| (%) | 430 nm | 84.19 | 84.85 | 84.85 |
| | 450 nm | 86.42 | 87.52 | 86.83 |
| | 550 nm | 89.63 | 90.23 | 88.73 |
| | 750 nm | 91.23 | 90.30 | 89.84 |
| Color | YI/b* | 4.33/2.46 | 3.90/2.29 | 3.19/1.80 |

Table 3 illustrates that the incorporation of certain amounts of cyclobutane dianhydride (CBDA) components into polyimide films can yield materials with a balance of properties well suited for the uses disclosed herein. In particular; a reduction in observed CTE is accompanied by low color and favorable optical transmission characteristics at both long wavelengths, where a high average transmission is desired, and shorter wavelengths, where some level of transmission is needed to enable the photolithography processes that are often used in the construction of a variety of electronic devices like those disclosed herein. Also, the incorporation of CBDA can allow films of higher T_{g} to be prepared at lower maximum imidization temperature. Finally, films containing CBDA-derived components can also exhibit higher tensile modulus.

### Example C—Preparation of Polyamic Acid Copolymer of 6FDA/CBDA/PMDA//TFMB 10/50/40//100 in NMP

This solution containing polyamic acid 6FDA/CBDA/PMDA//TFMB 10/50/40//100 was prepared in NMP in an analogous manner to that done in Examples A and B above, except that specific dianhydrides and diamines, and their respective relative amounts, were appropriate for this target composition. The prepared solution was poured into a 2-liter HDPE bottle, tightly capped, and stored in a refrigerator for later use.

### Example 3—Spin Coating and Imidization of Polyamic Acid Solution to 6FDA/CBDA/PMDA//TFMB 10/50/40//100 Polyimide Coating

In a manner analogous to that described above in Example 1, the solution containing the polyamic acid copolymer prepared in Example C was filtered, coated onto a 6″ silicon wafer, soft-baked, and imidized. Maximum cure temperature of the imidization temperature profile was 320° C. The heating was then stopped and the temperature allowed to return slowly to ambient temperature (no external cooling). Afterward, the wafers were removed from the furnace and the coatings were removed from the wafers by scoring the coating around the edge of the wafer with a knife and then soaking the wafers in water for at least several hours to lift the coating off the wafer. The resulting polyimide films allowed to dry and then subject to various property measurements. For example, a Hunter Lab spectrophotometer was used to measure b* and yellow index along with % transmittance (% T) over the wavelength range 350 nm-780 nm. Thermal measurements on films were made using a combination of thermogravimetric analysis and thermomechanical analysis as appropriate for the specific parameters reported herein. Mechanical properties were measured using equipment from Instron. Property measurements for this film are presented in Table 4.

### Comparative Example B—Preparation of Polyamic Acid Copolymer of PMDA/6FDA/BPDA//TFMB 2/48/50//100 in NMP

This solution containing polyamic acid PMDA/6FDA/BPDA//TFMB 2/48/50//100 was prepared in NMP in an analogous manner to that done in Comparative Example A above, except that specific dianhydrides and diamines, and their respective relative amounts, were appropriate for this target composition. The prepared solution was poured into a 2-liter HDPE bottle, tightly capped, and stored in a refrigerator for later use.

### Comparative Example 2—Spin Coating and Imidization of Polyamic Acid Solution to PMDA/6FDA/BPDA//TFMB 2/48/50//100 Polyimide Coating

In a manner analogous to that described above in Comparative Examples 1 above, the solution containing the polyamic acid copolymer prepared in Comparative Example B was filtered, coated onto a 6″ silicon wafer, soft-baked, and imidized. Maximum cure temperature of the imidization temperature profile was 350° C. The heating was then stopped and the temperature allowed to return slowly to ambient temperature (no external cooling). Afterward, the wafers were removed from the furnace and the coatings were removed from the wafers by scoring the coating around the edge of the wafer with a knife and then soaking the wafers in water for at least several hours to lift the coating off the wafer. The resulting polyimide films allowed to dry and then subject to various property measurements. For example, a Hunter Lab spectrophotometer was used to measure b* and yellow index along with % transmittance (% T) over the wavelength range 350 nm-780 nm. Thermal measurements on films were made using a combination of thermogravimetric analysis and thermomechanical analysis as appropriate for the specific parameters reported herein. Mechanical properties were measured using equipment from Instron. Property measurements for this film are presented in Table 4.

TABLE 4
Compositions/Properties of Polyimide Films

| | | Example 3 | Comparative Example 2 |
|---|---|---|---|
| Film | Composition | 6FDA/CBDA/PMDA//TFMB | PMDA/6FDA/BPDA//TFMB |
| Properties | (mole %) | 10/50/40//100 | 2/48/50//100 |
| | Cure Temp (° C.) | 320 | 350 |
| | Film Thickness | 9.76 | 9.79 |
| | (μm) | | |
| Thermal | T_{g} (° C.) | 387 | 350 |
| Properties | CTE | 19.35 | 49 |
| | (ppm/° C.) | | |
| | 1.0% TGA WT | 390.3 | 482.1 |
| | LOSS (° C.) | | |
| Mechanical | Tensile | 5.9 | 4.29 |
| Properties | Modulus (GPa) | | |
| | Tensile | 204 | 126.28 |
| | Strength (MPa) | | |
| | Elongation to | 8.7 | 13.87 |
| | Break (%) | | |
| Optical | 360 nm | 11.54 | 3.43 |
| Properties | 370 nm | 19.54 | 12.35 |
| Transmittance | 400 nm | 55.82 | 76.34 |
| (%) | 430 nm | 77.03 | 86.73 |
| | 450 nm | 82.62 | 88.16 |
| | 550 nm | 89.67 | 89.40 |
| | 750 nm | 91.35 | 89.77 |
| Color | YI/b* | 8.5/5.21 | 2.07/1.18 |

Table 4 results show that the incorporation of certain amounts of cyclobutane dianhydride (CBDA) components into polyimide films can yield materials with a balance of properties well suited for the uses disclosed herein. In particular, a reduction in observed CTE is accompanied by favorable optical transmission characteristics at shorter wavelengths, where some level of transmission is needed to enable the photolithography processes that are often used in the construction of a variety of electronic devices like those disclosed herein. Also, the incorporation of CBDA can allow films of higher T_{g} to be prepared at lower maximum imidization temperature. Polyimide films containing CBDA-derived components also exhibit increased tensile modulus and tensile strength.

### Examples D, E, F, G, H—Preparation of Polyamic Acid Copolymers in NMP with Compositions

### Example D

CBDA/BPDA//TFMB 40/60//100

### Example E

BPDA/CBDA/PMDA//TFMB 25/40/35//100

### Example F

PMDA/CBDA/ODPA//TFMB 85/5/10//100

### Example G

CBDA/PMDA/a-BPDA//TFMB 40/35/25//100

### Example H

PMDA/BPDA/CBDA/6FDA//TFMB 20/20/50/10//100

Solutions containing polyamic acid of the above compositions were prepared in NMP in using analogous steps to those disclosed for Examples A, B, and C above, except that specific dianhydrides and diamines, and their respective relative amounts, were appropriate for these target compositions. The prepared solutions were poured into a 2-liter HDPE bottles, tightly capped, and stored in a refrigerator for later use.

### Examples 4-8: Spin Coating and Imidization of Polyamic Acid Solutions with Compositions

### Example 4

CBDA/BPDA//TFMB 40/60//100

### Example 5

BPDA/CBDA/PMDA//TFMB 25/40/35//100

### Example 6

PMDA/CBDA/ODPA//TFMB 85/5/10//100

### Example 7

CBDA/PMDA/a-BPDA//TFMB 40/35/25//100

### Example 8

PMDA/BPDA/CBDA/6FDA//TFMB 20/20/50/10//100

In a manner analogous to those described above in Examples 1-3, the solutions containing the polyamic acid copolymers prepared in Examples D-H were filtered, coated onto a 6″ silicon wafer, soft-baked, and imidized. Maximum cure temperature of the imidization temperature profile was as reported in Tables 5a and 5b. In all cases, the heating was stopped and the temperature allowed to return slowly to ambient temperature (no external cooling). Afterward, the wafers were removed from the furnace and the coatings were removed from the wafers by scoring the coatings around the edges of the wafers with a knife and then soaking the wafers in water for at least several hours to lift the coatings off the wafers. The resulting polyimide films were allowed to dry and then subject to various property measurements. For example, a Hunter Lab spectrophotometer was used to measure b* and yellow index along with % transmittance (% T) over the wavelength range 350 nm-780 nm. Thermal measurements on films were made using a combination of thermogravimetric analysis and thermomechanical analysis as appropriate for the specific parameters reported herein. Mechanical properties were measured using equipment from Instron. Property measurements for this film are presented in Tables 5a and 5b.

TABLE 5a
Compositions/Properties of Polyimide Films

| | | Example 4 | Example 5 |
|---|---|---|---|
| Film | Composition | CBDA/BPDA//TFMB | BPDA/CBDA/PMDA//TFMB |
| Properties | (mole %) | 40/60//100 | 25/40/35//100 |
| | Cure Temp (° C.) | 320 | 320 |
| | Film Thickness | 10.1 | 9.59 |
| | (μm) | | |
| Thermal | T_{g} (° C.) | 358 | 375 |
| Properties | CTE | 32.84 | 14.03 |
| | (ppm/° C.) | | |
| | 1.0% TGA WT | 402.21 | 391.73 |
| | LOSS (° C.) | | |
| Mechanical | Tensile | 5.54 | 7.08 |
| Properties | Modulus (GPa) | | |
| | Tensile | 160.01 | 238.12 |
| | Strength (MPa) | | |
| | Elongation to | 9.15 | 20.19 |
| | Break (%) | | |
| Optical | 360 nm | 1.71 | 2.06 |
| Properties | 370 nm | 5.21 | 6.75 |
| Transmittance | 400 nm | 64.75 | 52.34 |
| (%) | 430 nm | 83.01 | 75.87 |
| | 450 nm | 86.42 | 82.45 |
| | 550 nm | 88.84 | 87.75 |
| | 750 nm | 91 | 90.86 |
| Color | YI/b* | 4.18/2.39 | 8.2/4.95 |

TABLE 5b
Compositions/Properties of Polyimide Films

| | | Example 6 | Example 7 | Example 8 |
|---|---|---|---|---|
| Film | Composition | PMDA/CBDA/ODPA//TFMB | CBDA/PMDA/a-BPDA//TFMB | PMDA/BPDA/CBDA/6FDA//TFMB |
| Properties | (mole %) | 85/5/10//100 | 40/35/25//100 | 20/20/50/10//100 |
| | Cure Temp (° C.) | 320 | 320 | 320 |
| | Film Thickness | 9.92 | 9.71 | 10.14 |
| | (μm) | | | |
| Thermal | T_{g} (° C.) | 357 | 358 | 374 |
| Properties | CTE | −1.72 | 31.53 | 26.81 |
| | (ppm/° C.) | | | |
| | 1.0% TGA WT | 447.86 | 395 | 398.03 |
| | LOSS (° C.) | | | |
| Mechanical | Tensile | 8.31 | 5.8 | |
| Properties | Modulus (GPa) | | | |
| | Tensile | 261.22 | 179 | |
| | Strength (MPa) | | | |
| | Elongation to | 17.58 | 5.1 | |
| | Break (%) | | | |
| Optical | 360 nm | 1.7 | 7.75 | 4.24 |
| Properties | 370 nm | 4.51 | 17.50 | 13.22 |
| Transmittance | 400 nm | 37.62 | 57.60 | 63.02 |
| (%) | 430 nm | 70.35 | 78.00 | 80.89 |
| | 450 nm | 79.75 | 83.80 | 84.93 |
| | 550 nm | 87.36 | 89.50 | 89.26 |
| | 750 nm | 89.01 | 90.60 | 90.89 |
| Color | YI/b* | 11.59/7.12 | 7.83/4.78 | 6.22/3.65 |

Examples presented in Tables 5a and 5b further illustrate the balance of thermal, mechanical, and optical properties that can be achieved in CBDA-based polyimide films. The particular composition chosen, and the specific imidization conditions employed, are determined by the end-use of interest in each case.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. The use of numerical values in the various ranges specified herein is stated as approximations as though the minimum and maximum values within the stated ranges were both being preceded by the word “about.” In this manner, slight variations above and below the stated ranges can be used to achieve substantially the same results as values within the ranges. Also, the disclosure of these ranges is intended as a continuous range including every value between the minimum and maximum average values including fractional values that can result when some of components of one value are mixed with those of different value. Moreover, when broader and narrower ranges are disclosed, it is within the contemplation of this invention to match a minimum value from one range with a maximum value from another range and vice versa.

What is claimed is:

1. A solution composition comprising a polyamic acid in a high-boiling, aprotic solvent; wherein
the polyamic acid comprises two or more tetracarboxylic acid components and one or more diamine components; and wherein
at least one of the tetracarboxylic acid components is a quadrivalent organic group derived from an aliphatic dianhydride.

2. The solution composition of claim 1, wherein the tetracarboxylic acid components are derived from dianhydrides selected from the group consisting of 3,3′,4,4′-biphenyltetracarboxylic dianhydride (BPDA) and cyclobutene dianhydride (CBDA).

3. The solution composition of claim 2, wherein the tetracarboxylic acid components additionally comprise components derived from dianhydride 4,4′-(hexafluoroisopropylidene) diphthalic anhydride (6FDA).

4. A polyimide film prepared from the solution composition of claim 1.

5. The polyimide film of claim 4, wherein the polyimide film comprises the repeat unit of Formula I 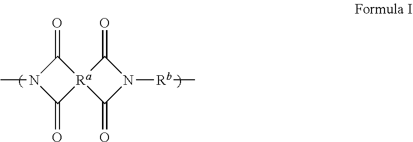
wherein:
R^{a} is a quadrivalent organic group derived from two or more acid dianhydrides wherein at least one of the acid dianhydrides is an aliphatic dianhydride and R^{b} is a divalent organic group derived from one or more diamines;
such that:
the in-plane coefficient of thermal expansion (CTE) is less than 40 ppm/° C. between 50° C. and 250° C.;
the glass transition temperature (T_{g}) is greater than 300° C. for a polyimide film cured at a temperature above 300° C.;
the 1% TGA weight loss temperature is greater than 350° C.;
the tensile modulus is greater than 5 GPa;
the transmittance at 360 nm is greater than 5%;
the transmittance at 370 nm is greater than 10%;
the transmittance at 400 nm is greater than 40%;
the transmittance at 430 nm is greater than 80%;
the transmittance at 450 nm is greater than 85%;
the transmittance at 550 nm is greater than or equal to 88%; and
the b* is less than 3.0.

6. The polyimide film of claim 5, wherein the in-plane coefficient of thermal expansion (CTE) is less than 20 ppm/° C. between 50° C. and 250° C.

7. A method for preparing a polyimide film, said method selected from the group consisting of a thermal method and a modified-thermal method, wherein the thermal method comprises the following steps in order:
coating the solution of claim 2 onto a matrix;
soft-baking the coated matrix;
treating the soft-baked, coated matrix at a plurality of pre-selected temperatures for a plurality of pre-selected time intervals;
whereby the polyimide film exhibits:
an in-plane coefficient of thermal expansion (CTE) that is less than 40 ppm/° C. between 50° C. and 250° C.;
a glass transition temperature (T_{g}) that is greater than 300° C. for a polyimide film cured at a temperature above 300° C.;
a 1% TGA weight loss temperature that is greater than 350° C.;
a tensile modulus is greater than 5 GPa;
a transmittance at 360 nm that is greater than 5%;
a transmittance at 370 nm that is greater than 10%;
a transmittance at 400 nm that is greater than 40%;
a transmittance at 430 nm that is greater than 80%;
a transmittance at 450 nm that is greater than 85%;
a transmittance at 550 nm that is greater than or equal to 88%; and
a b* that is less than 3.0.

8. The method of claim 7, wherein the method is a modified thermal method; and the maximum pre-selected temperature is 260° C.

9. A flexible replacement for glass in an electronic device wherein the flexible replacement for glass comprises a polyimide film according to claim 4.

10. An electronic device comprising the flexible replacement for glass according to claim 4.

11. The electronic device of claim 10 wherein the flexible replacement for glass is used in device components selected from the group consisting of device substrate, touch panel, cover film, and color filter.
